(19) United States
(12) Patent Application Publication
(10) Pub. No.: US 2026/0278221 A1
(43) Pub. Date: Sep. 17, 2026

(54) SYSTEMS AND METHODS FOR INVERSE DESIGN OF OPTICAL MULTILAYER THIN FILM STRUCTURES UTILIZING A FOUNDATION MODEL

(71) Applicant: The Regents of The University of Michigan, Ann Arbor, MI (US)

(72) Inventors: Taigao MA, Ann Arbor, MI (US); Lingjie Jay GUO, Ann Arbor, MI (US); Haozhu WANG, Mount Prospect, IL (US)

(73) Assignee: The Regents of The University of Michigan, Ann Arbor, MI (US)

(21) Appl. No.: 19/474,821

(22) PCT Filed: Apr. 15, 2024
(86) PCT No.: PCT/US2024/024563

§ 371 Date: Oct. 13, 2025

Related U.S. Application Data
(60) Provisional application No. 63/459,433, filed on Apr. 14, 2023.

(51) Int. Cl. G06F 30/27; G02B 27/00

(52) U.S. Cl. CPC G06F 30/27; G02B 27/0012

(57) ABSTRACT

Systems and methods for inverse design of an optical multilayer thin film structure are provided and include receiving optical target parameters based on an input prompt and applying the received optical target parameters to a foundation model having a transformer that includes a family of neural network models and that utilizes structure serialization using tokens to represent materials and thicknesses of layers of optical multilayer thin film structures and that utilizes spectrum embedding to facilitate learning, by the model, of relationships between spectra and structure. Data representing an optical multilayer thin film structure is generated based on an application of the foundation model to the optical target parameters, the optical multilayer thin film structure having optical properties that satisfy the received optical target parameters, and outputted.

### CROSS-REFERENCE TO RELATED APPLICATIONS

This application claims the benefit of U.S. Provisional Application No. 63/459,433, filed on Apr. 14, 2023. The entire disclosure of the above application is incorporated herein by reference.

### GOVERNMENT LICENSE RIGHTS

This invention was made with government support under 2213684 awarded by the National Science Foundation. The government has certain rights in the invention.

### FIELD

The present disclosure relates to inverse design of optical multilayer thin film structures and, more particularly, to systems and methods for inverse design of optical multilayer thin film structure utilizing a foundation model.

### BACKGROUND

This section provides background information related to the present disclosure which is not necessarily prior art.

Optical multilayer thin film structures are a vital class of photonic structures used in many applications, including spectrum filters, such as bandpass filters, band notch filters, etc., absorbers, such as narrow or broadband absorbers, structural colors, distributed brag reflectors, and Fabry-Pérot resonators. Simulating a multilayer structure can be performed using transfer matrix methods. However, inverse design is a non-trivial task since both the arrangement of material choices and the thickness at each layer should be considered. Existing methods either fail to include freedom to choose materials into design process or suffer from computational efficiency.

Designing a multilayer structure involves determining the material choice at each layer and the corresponding thicknesses of the layers. The major reason that existing deep learning-based methods cannot accommodate different types of structures is that the output of these neural networks has a fixed size that corresponds to a pre-defined structure, e.g., the three-layer structure of Ag/SiO₂/Ag, the six-layer structure of MgF₂/SiO₂/Al₂O₃/TiO₂/Si/Ge, and the twenty-layer structure of alternating SiO₂/Si₃N₄. Therefore, these models can only design thickness for each layer and do not allow different material choices.

The inverse design of multilayer structures requires identifying the best material arrangements and obtaining thickness combinations to achieve user-desired optical targets. In previous methods, material arrangements were specified based on domain expertise and simplified inverse design as iterative thickness optimization, with methods including particle swarm optimization, needle optimization, and genetic algorithms. The optimization-based methods usually rely on numerical simulations and iterative searches to minimize the difference between simulated and targeted optical properties. However, a high-performance design may not be discovered if the human-specified material arrangement is not optimal. A global design method that can determine the total number of layers and material arrangements will broaden the design space significantly and lead to better performance.

The main difficulty of global design originates from the fact that materials are usually dispersive, making design problems more intractable for broadband applications. Recently, several methods have been proposed to overcome this challenge. For example, a memetic algorithm incorporated the material into the design process and designed a high-performance radiative cooling device. Another has framed the inverse design as a sequence generation and developed a reinforcement learning-based algorithm OML-PPO to determine the number of layers and material combinations automatically. Finally, yet another suggested combined GLOnet17 with the reconciled level set method to optimize both material and thickness for the optical transfer function. However, all these methods are inefficient because they require iterative evaluations and time-consuming simulations, which can be problematic when the target changes as a new design process from scratch will be needed.

In order to make the design process more efficient, many deep-learning-based methods have been proposed and explored, including tandem networks18, GANs19, and MDNs20,21. Because of the strong generalization ability of neural networks, these methods can learn a general mapping from the space of optical targets to the space of optical multilayer thin film structures. After training on a dataset, they can generate designs instantaneously for different targets without iterative and time-consuming evaluations and simulations. Unfortunately, although efficient, they fail to accommodate the global design. This is because all of these neural networks have fixed output size that do not allow material selections and structures with different number of layers.

Previous algorithms cannot simultaneously remedy the challenge of global and efficient design.

### SUMMARY

This section provides a general summary of the disclosure, and is not a comprehensive disclosure of its full scope or all of its features.

In this disclosure structure tokens and structure serialization are used to obtain the collaborative representation of materials and their thicknesses at the same time by treating the inverse design task as a conditional sequence generation problem.

In one aspect of the disclosure, a method of inverse designing an optic multi-layer thin film structure includes receiving optical targets to a foundation model comprising a plurality of sequential decoders, said optical targets comprises a target spectrum, receiving a hidden representation of the optical targets at the plurality of sequential decoders, receiving physical embeddings and positional embeddings at a first decoder of the plurality of sequential decoders, coupling an output of a previous decoder to a subsequent decoder of the plurality of sequential decoders and generating a sequence of tokens and probabilities representing a material and thickness for a plurality of layers of an optical multilayer thin film structure.

A system is provided and includes a computer-readable medium storing code for a foundation model having a transformer that includes neural network models and that utilizes structure serialization using tokens to represent materials and thicknesses of layers of optical multilayer thin film structures and that utilizes spectrum embedding to facilitate learning, by the model, of relationships between spectra and structure. The computer-readable medium also stores computer executable instructions that, when executed by a processor, configure the processor to: receive optical target parameters as an input prompt; generate data representing an optical multilayer thin film structure, based on the foundation model and the optical target parameters, the optical multilayer thin film structure having optical properties that satisfy the received optical target parameters; and output the data representing the optical multilayer thin film structure.

In other features, the data representing the optical multilayer thin film structure indicates a total number of layers of the optical multilayer thin film structure required to satisfy the optical target parameters and indicates a material and a thickness for each layer of the optical multilayer thin film structure.

A method for inverse design of an optical multilayer thin film structure is also provided and includes: receiving, with at least one processor, optical target parameters based on an input prompt; applying, with the at least one processor, the received optical target parameters to a foundation model having a transformer that includes neural network models and that utilizes structure serialization using tokens to represent materials and thicknesses of layers of optical multilayer thin film structures and that utilizes spectrum embedding to facilitate learning, by the model, of relationships between spectra and structure; generating, with the at least one processor, data representing an optical multilayer thin film structure, based on an application of the foundation model to the optical target parameters, the optical multilayer thin film structure having optical properties that satisfy the received optical target parameters; and outputting, with the at least one processor, the data representing the optical multilayer thin film structure.

In other features, the data representing the optical multilayer thin film structure indicates a total number of layers of the optical multilayer thin film structure required to satisfy the optical target parameters and indicates a material and a thickness for each layer of the optical multilayer thin film structure.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a generative pre-trained transformer according to the prior art.

FIG. 2A is a high level block diagrammatic of an Opto-Generative Pretrained Transformer system in accordance with the present disclosure for designing multilayer thin film structures.

FIG. 2B a schematic of an Opto-Generative Pretrained Transformer system in accordance with the present disclosure.

FIG. 2C is a diagram of design targets for the system.

FIG. 2D. is a representation of a layer structure and tokens generated by the system.

FIG. 3A is a high-level block diagram of the transformer of FIG. 2A.

FIG. 3B is a block diagram of a training structure for the present disclosure.

FIG. 3C shows a diagrammatic view illustrating the auto-regressive process of the present disclosure.

FIG. 4A illustrates two-dimensional visualization of hidden space using t-SNE to reduce dimension in accordance with the present disclosure.

FIG. 4B illustrates enlarged two-dimensional visualizations using the t-SNE process.

FIG. 5A illustrates examples of Mean Absolute Error (MAE) on random target using closest, designed and finetuned results.

FIG. 5B is a plot of the number of target layers versus layers in a design structure.

FIG. 5C is a table of simulation time and design time.

FIG. 5D is an example of an inverse design from a validation set in accordance with the present disclosure.

FIG. 5E is a table of data corresponding to FIG. 5D.

FIG. 6A illustrates a design for a band notch filter for artificial spectra formed in accordance with the present disclosure.

FIG. 6B illustrates a design for a high reflection filter in near-infrared for artificial spectra formed in accordance with the present disclosure.

FIG. 6C illustrates a design for a perfect absorber for artificial spectra formed in accordance with the present disclosure.

FIG. 6D illustrates a design for an arbitrary absorber for artificial spectra formed in accordance with the present disclosure.

FIG. 6E is a table illustrating delta E for reflective and transmissive color differences.

FIG. 7A is a probability plot of the transformer based on an applied constraint.

FIGS. 7B-7D are plots of efficiency versus wavelength with different constraints.

FIG. 8A is a diagrammatic view for finetuning using different polarizations.

FIGS. 8B-8G are plots of efficiency versus wavelength with different polarizations.

FIG. 9A is a diagram for a mixed sampling example.

FIGS. 9B-9D are efficiency-versus-wavelength plots for different angle-robust spectrums.

FIGS. 10A and 10B illustrate measured refractive index real part and imaginary part, respectively, for 18 materials in accordance with the present disclosure.

FIGS. 11A and 11B illustrate a histogram of numbers of generated training data with respect to number of layers in accordance with the present disclosure.

FIG. 11B illustrates a histogram of a number of allowable structures with respect to number of layers in accordance with the present disclosure.

FIGS. 12A-12E illustrate a data set with four examples.

FIG. 12B is a plot of efficiency versus wavelength plot for the four examples in FIG. 12A in accordance with the present disclosure.

FIG. 13A is a table of hyperparameters and values thereof used in the present disclosure.

FIG. 13B illustrates training and validation loss curves in accordance with the present disclosure.

FIGS. 14A-14C illustrate multi-head attention maps for a structure in accordance with the present disclosure.

FIG. 15A illustrates details of a finetuning process for the thickness in accordance with the present disclosure.

FIGS. 15B-15C illustrate a plot of spectrum versus iterations for a BFGS and PSO optimization in accordance with the present disclosure.

FIGS. 16A-16B illustrate a plot of efficiency versus wavelength for a first example of inverse design and a dataset corresponding thereto in accordance with the present disclosure.

FIGS. 16C-16D illustrate a plot of efficiency versus wavelength for a second example of an inverse design and dataset corresponding thereto in accordance with the present disclosure.

FIG. 17 illustrates color matching functions for CIE 1931 2 degree standard observer in accordance with the present disclosure.

FIG. 18 illustrates converting LAB color to spectrum using different alpha factors in accordance with the present disclosure.

FIG. 19 illustrates examples of inverse design reflective and transmissive type structure colors in accordance with the present disclosure.

FIGS. 20A-20C illustrate plots of efficiency versus wavelength for two inverse designs of perfect absorbers in 400-1100 nm and a data chart in accordance with the present disclosure.

FIGS. 21A-21D illustrate plots of efficiency versus wavelength for two inverse designs of arbitrary absorbers in 400-1100 nm and data charts in accordance with the present disclosure.

FIGS. 22A-22D illustrate plots of efficiency versus wavelength for two inverse designs of band notch filters in 400-1100 nm and data charts in accordance with the present disclosure.

FIGS. 23A-23D illustrate plots of efficiency versus wavelength for two inverse designs of high reflectance devices in 400-1100 nm and data charts in accordance with the present disclosure.

FIGS. 24A-24D illustrate plots of efficiency versus wavelength for two inverse designs of Fabry-Perot resonator cavities with four different constrains in 400-1100 nm and a data chart in accordance with the present disclosure.

FIG. 25A illustrates an example of design flexibility for transmissive orange structural color in accordance with the present disclosure.

FIG. 25B is a data table used in the example of FIG. 25A.

FIG. 26 Is a table of a comparison of different design methods.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various steps, elements, components, regions, layers and/or sections, these steps, elements, components, regions, layers and/or sections should not be limited by these terms, unless otherwise indicated. These terms may be only used to distinguish one step, element, component, region, layer or section from another step, element, component, region, layer or section. Terms such as “first,” “second,” and other numerical terms when used herein do not imply a sequence or order unless clearly indicated by the context. Thus, a first step, element, component, region, layer or section discussed below could be termed a second step, element, component, region, layer or section without departing from the teachings of the example embodiments.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. Other than in the working examples provided at the end of the detailed description, all numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters. For example, “about” may comprise a variation of less than or equal to 5%, optionally less than or equal to 4%, optionally less than or equal to 3%, optionally less than or equal to 2%, optionally less than or equal to 1%, optionally less than or equal to 0.5%, and in certain aspects, optionally less than or equal to 0.1%.

In addition, disclosure of ranges includes disclosure of all values and further divided ranges within the entire range, including endpoints and sub-ranges given for the ranges.

Example embodiments will now be described more fully with reference to the accompanying drawings.

For a long time, photonic inverse design was regarded as a much more difficult problem than simulation and has presented high entry barriers for those interested in searching for the optical design in specific applications. The system, in accordance with the present disclosure, makes multilayer thin film structure-based inverse design an equally accessible task as the traditional optical simulation for a multilayer thin film structure. By treating inverse design as a sequence generation conditioned on the optical targets and using a large-scale dataset for training, the system set forth in the present disclosure outperforms all the existing inverse design methods on four aspects. The system is referred to as the OptoGPT system or simply OptoGPT herein. OptoGPT is a system that acts as a foundation model, or simply model, for multilayer thin film inverse design to make the inverse design as easy, fast, and straightforward as running a simulation.

The findings of the present disclosure regarding the hidden representations of OptoGPT suggest that it has acquired domain-specific knowledge pertaining to optical multilayer structures through the training process. Furthermore, the model of the present disclosure has demonstrated the capacity to apply this acquired knowledge effectively in the inverse design process.

The present disclosure is directed to the inverse design of optical multilayer thin film structures utilizing a foundation model. Material and thickness are treated equally by concatenating them together to form a “structure token”. By adding the tokens one by one, a multilayer structure is converted into a sequence, which will be referred as a “structure serialization.” Structure serialization. With these two combined techniques, the OptoGPT system design in the global space automatically determines the total number of layers and determines materials and thicknesses at each layer. The model of the present disclosure, for example, can consider 18 distinct types of materials and design structures with up to 20 layers, making the total number of possible structures approximately 10⁵⁹. Other numbers of distinct types of materials and layers, however, can be used, resulting in additional possible structures, in accordance with the present disclosure. Finish multiple design tasks efficiently, including structural color, absorbers, filters, distributed brag reflectors, and Fabry-Pérot resonators. On average, each design task can be completed, for example, within 0.1 seconds, close to the time running a simulation using transfer matrix methods. The present system can output as many different designs as desired, which can provide high freedom for fabrication. Further, the system automatically learns the intricate relationship between materials space and the response space. Any constraints on the material selection and the material thickness range may be incorporated into the design process with minimal effort. For example, when specifying the material arrangements, the model can output the thickness directly without iterative optimization. In addition, the present system also works for inclined incidence, various output angles and different polarization by finetuning the model on a small dataset.

The OptoGPT system of the present disclosure eliminates design barriers regarding optical targets, material selections, and design constraints, incident angles and polarization, making inverse design tasks in multilayer structures approaching “solved”. The OptoGPT system is similar to a “foundation model” in computer science, i.e., a large machine-learning model that can be adapted to a wide range of downstream tasks after training in a large dataset. The results establish that the OptoGPT system can be used as a foundation model for inverse design in multilayer structures, which can streamline the inverse design process and accelerate the development of advanced optical systems. Furthermore, by serving as a reliable starting point for researchers and engineers, the model facilitates the exploration of novel designs and the optimization of optical performance within the constraints of material properties and fabrication techniques.

The OptoGPT system of the present disclosure is the first application of GPT to a particular domain of optical science. The two techniques noted above, i.e., structure serialization and spectrum embedding, make GPT well-suited to the multilayer structure inverse design problems. Further, the two techniques are versatile and can be applied to solve other types of inverse design problems. For example, metasurfaces and free-form waveguide structures can be serialized using a patch of images; spectrum embeddings can be extended to include other design targets, including angled-resolved spectrum, radiative patterns, phase information, and the like. In this way, the OptoGPT system of the present disclosure can be used to perform other types of inverse design problems based on the two implementations. In addition, a multi-modal GPT can unite different types of photonic structures and design targets, creating a more powerful foundation model to design all photonic structures for versatile optical targets.

In addition, the GPT-based method of the present disclosure can go beyond photonic inverse design to solve general inverse tasks as long as there exists a physical relationship between cause and effect, e.g., recovering the phase facts from intensity images, extracting refractive index from spectrum measurement, or recovering volume information from images. This is because most inverse tasks can be formulated as generation tasks conditioned on the input, which can be solved using similar GPT-based architecture. As such, the GPT-based method of the present disclosure can revolutionize the optical society and tackle many complicated and unsolved problems.

Referring now to FIG. 1, Generative Pretrained Transformers (GPT) 10 are widely-used large language models used for natural language processing. Such systems receive input prompts 12 from a user interface. The transformer 10 processes the input to generate a probability output 14 that corresponds to a single answer for each input prompt 12. GPT is an auto-regressive language model that produces text output given the initial text as the input prompt 12. The initial prompt 12 can be a question, a task description, or anything necessary for the model to understand what to expect as outputs. During training, pairs of text input prompts 12 and expected answers are fed together to the GPT 10, with the training goal of recovering the expected answers from the model's probability output. GPT is only known to only take in the text prompt and answers will be generated auto-regressively.

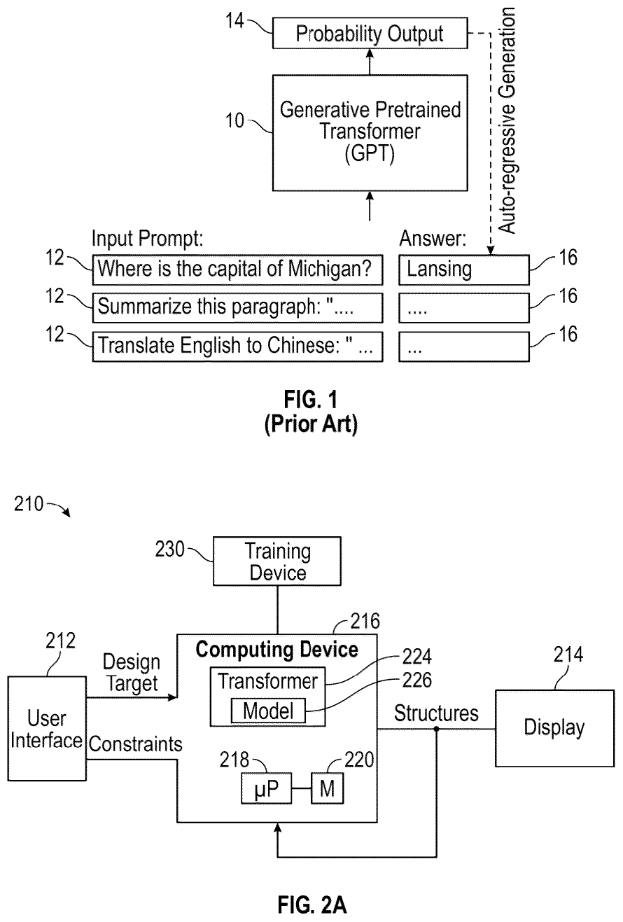

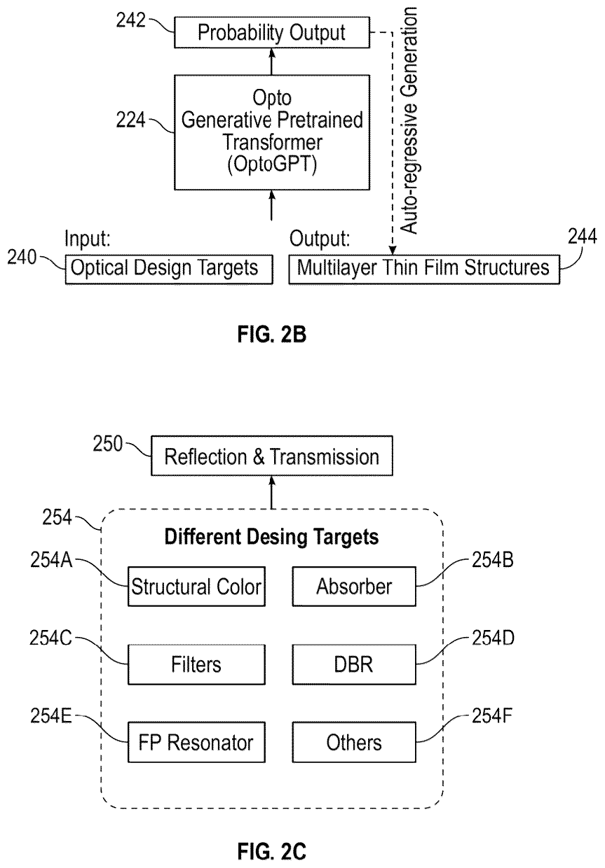

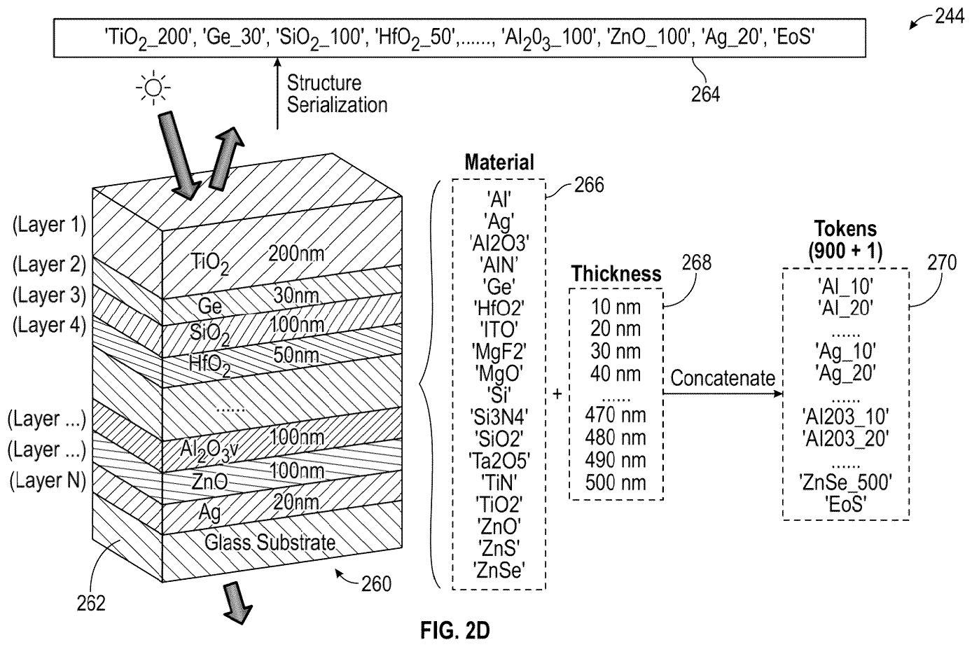

Referring now to FIG. 2A, the present disclosure provides a system that is referred to as the OptoGPT system 210. The system 210 has a user interface 212. The user interface 212 may be comprised of a keyboard, a mouse, a touch screen display, another input device or other combinations thereof. The touch screen display may be part of a display 214. The display 214 may display structure sequences of tokens or other representations of a multilayer optical structure formed according to the present disclosure. The display 214 may display a structural sequence for one or more layered thin film optical structures that include materials, thicknesses and the relative position of the layers.

A computing device 216 is in communication with the user interface 212 and the display 214. The computing device 216 has a microprocessor or processor 218 in communication with a memory 220. The memory 220 is a non-transitory computer-readable medium that includes machine readable instructions that are executable by the processor 218. The instructions are used to perform various functions as described below including determining a structural sequence for layered thin film optical structures that include materials, thicknesses and the relative position of the layers. Although a single processor 218 is illustrated, multiple processors may be provided. For example, a graphics processor may be used. Likewise, multiple computing devices 216 may act together to perform the various functions.

The computing device 216 includes a transformer 224. The transformer 224 may be referred to as an Opto Generative Pretrained Transformer (OptoGPT). The transformer 224 includes neural network models 226 stored therein.

Training device 230 is in communication with the computing device 216. The training device 230 provides training data to the transformer 224 so that the determination of thin film optical structure may be generated using design targets and constraints provided by the user interface 212. Specifically, the OptoGPT system 210 takes optical target parameters or simply optical targets as the input prompt and outputs a corresponding multilayer structure design. In one example, a training dataset is provided by the training device 230 that was generated with 10 million randomly generated samples for training. For example, a model 226 associated with the transformer 224 was trained for about two weeks using a NVIDIA 3090 GPU (processor). After training, the model 226 can be used for inverse design directly regardless of the spectrum targets and design constraints.

Referring now to FIG. 2B, the transformer 224 is illustrated coupled to optical design targets 240. Probability output 242 is generated by the transformer 224 using the neural network model 226. The probability output 242 is used to provide probabilities that are used to determine a multi-layer thin film structure 244 or data representing thereof.

Referring now to FIG. 2C, several examples of input prompts are illustrated. In order to unify the space of design targets in various applications, all design targets are converted to reflection and transmission spectrum data 250 under normal incidence. The considered wavelength covers the visible and near-infrared (NIR) region, spanning from 400 nm to 1100 nm with 10 nm spacing. The design targets are input to the system 210 using the user interface 212 shown in FIG. 2A.

Different design targets 254 are considered including structural color 254A, absorbers 254B, filters 254C, distributed Bragg reflectors (DBR) 254D, Fabry-Pérot (FP) resonators 254E and other arbitrary spectrum targets 254F. All design targets 254 are converted to reflection and transmission spectrum data 250 and provided as the optical design target 240 of FIG. 2B from 400 nm to 1100 nm under normal incidence.

Referring now to FIG. 2D, an example of the multilayer thin film structures 244 of FIG. 2B is illustrated as a structural serialization in a N-layer structure 260 on a glass substrate 262. In this example, Layers 1-Layer N are illustrated. The N-layer structure 260 is serialized by N+1 tokens 264. The first N tokens 264 formed by concatenating the material and thickness at each layer are serialized in an order corresponding to the order to be formed on the glass substrate 262. By way of example, the first token of the tokens 264, for example, shows titanium dioxide with a 200 nm thickness (TiO₂_200). The last token is “EoS,” for End of Sequence. At each layer in this example, there are 18 possible types of materials 266 and 50 different thicknesses 268 (10 nm discretization in [10, 500] nm). The refractive index of each material is discussed in further detail below. Therefore, for each layer in the multilayer structure, there are 18×50+1=901 possible tokens, corresponding to 900 different combinations of material and thickness plus one special “EoS” token.

During inverse design, the transformer 224 generates a probability distribution 270 for all 901 tokens at the probability output 242 of FIG. 2B. Sampling from this distribution gives the design at each layer. If “EoS” is sampled, the OptoGPT system 210 terminates the design process and outputs the existing sequence as the designed structure. When the designed structure reaches the maximum number of layers, the design process will also terminate and output the existing sequence as the designed structure. The maximum number of layers is set to be 20, making the total number of multilayer structures under design consideration to be (901)²⁰ which is about 1.24×10⁵⁹. While 20 is used in the current example for the maximum number of layers, the maximum number of layers can be set to be higher or lower, in accordance with the present disclosure. Utilizing this approach, the model of the present disclosure can determine the total number of layers required for a given design target, as well as select the appropriate material and thickness for each individual layer.

The present disclosure utilizes the Opto Generative Pretrained Transformer (OptoGPT) 224 to resolve the conflict between global design and efficient design. Similar to other GPT models like GPT-3 and ChatGPT, the OptoGPT system 210 of the present disclosure is a decoder-only transformer that generates multilayer structures layer-by-layer in an auto-regressive way. In order to incorporate materials into the design process, the systems and methods of the present disclosure utilize structure serialization that uses a token to represent the material and thickness of a layer simultaneously. The systems and methods of the present disclosure also apply spectrum embedding to facilitate the learning of the complex relationship between spectra and structure. In this way, the model of the present disclosure can design in the global space and can determine the total number of layers (up to 20 layers, for example), materials (up to 18 types, for example), and thickness simultaneously. In addition, the systems and methods of the present disclosure utilize a large dataset comprising, for example, 10 million designs for training. This large-scale dataset enables the model to capture complicated relationships and expands the model's design ability towards diverse applications, including structural colors, filters, absorbers, DBR, and Fabry-Pérot (FP) resonators. The model of the present disclosure is efficient in all of these design applications. For example, the OptoGPT system 210 can complete each design within 0.1 seconds, on average, while consistently achieving design results better than those of baseline methods. Benefiting from the design efficiency, the model of the present disclosure can also output multiple designs with minimal effort and exhibit high design flexibility under different design constraints, which are beneficial for fabrication and design considerations. The constraints provide various limitations for various material types, thicknesses, or material placement. Given the constraint of material arrangements at each layer, the OptoGPT system 210 functions as a direct thickness optimizer that circumvents the iterative optimization process.

Based on the empirical results obtained, the OptoGPT system 210 can serve as a foundation model for the design of optical multilayer thin films across a diverse array of applications. By offering highly performant initial optical designs with computational efficiency, the model of the present disclosure can streamline the design process, reduce the need for extensive manual iterations, and accelerate the development of advanced optical systems. Furthermore, by serving as a reliable starting point for researchers and engineers, the model of the present disclosure facilitates the exploration of novel designs and the optimization of optical performance within the constraints of material properties and fabrication techniques. As such, the OptoGPT system 210 enhances the accessibility and effectiveness of optical design methodologies.

Foundation models are large machine learning models that can tackle various downstream tasks once trained on diverse and large-scale data, leading research trends in natural language processing, computer vision, and reinforcement learning. However, foundation models have not previously been used for optical multilayer thin film structure inverse design. Current inverse design algorithms either fail to explore the global design space or suffer from low computational efficiency. To bridge this gap, the present disclosure utilizes an Opto Generative Pretrained Transformer (OptoGPT), which is a decoder-only transformer that auto-regressively generates designs based on specific spectrum targets. Trained on a large dataset of 10 million designs, the model in accordance with the present disclosure demonstrates remarkable capabilities, including: 1) autonomous global design exploration by determining the number of layers, up to 20 for example, while selecting the material, up to 18 distinct types for example, and thickness at each layer; 2) efficient designs for structural color, absorbers, filters, distributed brag reflectors, and Fabry-Pérot resonators within 0.1 seconds (comparable to simulation speeds); 3) the ability to output diverse designs; and 4) seamless integration of user-defined constraints. By overcoming design barriers regarding optical targets, material selections, and design constraints, the OptoGPT system serves as a foundation model for optical multilayer thin film structure inverse design.

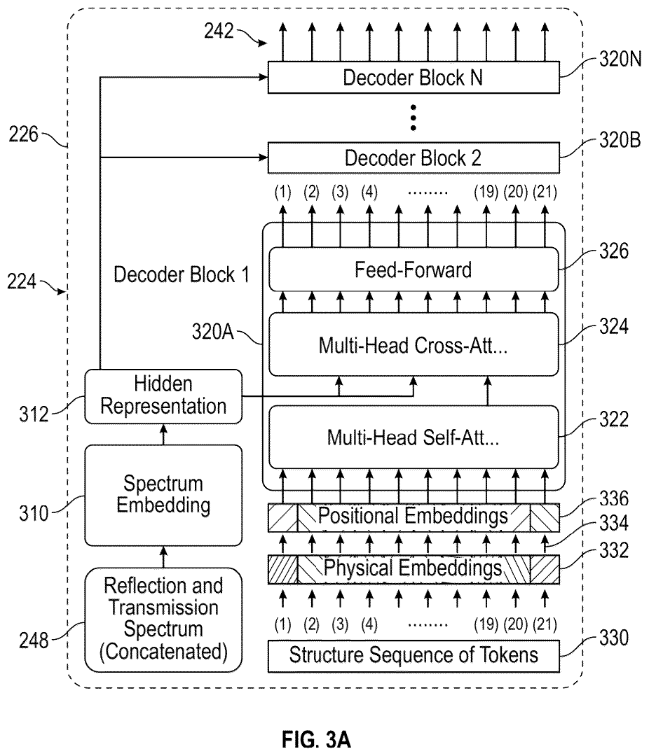

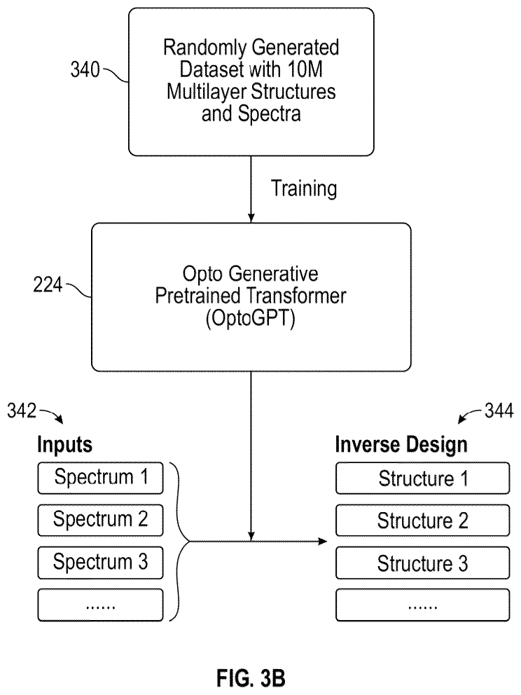

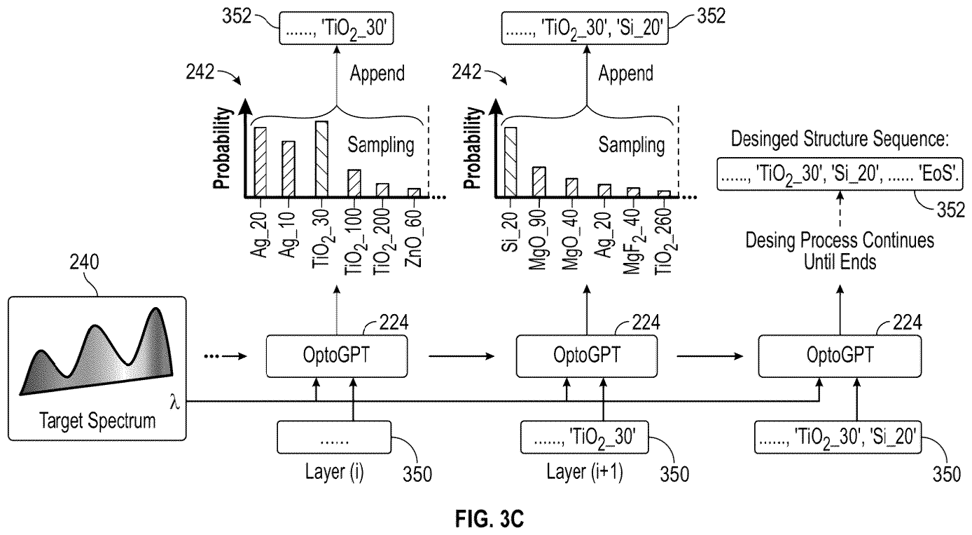

Referring now to FIG. 3A, the architecture of the transformer 224 and the neural network models or model 226 for auto-regressively forming a sequential layer structure is set forth in greater detail. There are two inputs to the transformer 224 and model 226. The first input is the optical design target 240 or “spectrum target.” A spectrum embedding 310 is determined from the optical design target 240 to obtain a high-dimension hidden representation 312 that is provided to each of the plurality of N sequential decoders. A second decoder 320B receives the output of the first decoder 320A and so on until the output of the last decoder 320N of the plurality of N decoders. That is, each subsequent decoder of the plurality of sequential decoders receives the output of the previous decoder. Each decoder 320A-320N comprises a multi-head self-attention block 322 which in turn feeds a multi-head cross-attention block 324 which feeds a feed forward block 326 that provides an output to the next decoder or the final output decoder 320N of the model 226.

Structure tokens in a structure token sequence 330 are used to provide constraints to the transformer 224. Structure tokens can have many forms including specifying or excluding certain materials, limiting the number of layers, providing the design targets 254 for the type of optical structure, certain layer thickness and the like. Structure tokens in a structure token sequence 330 will first go through a physical embedding layer 332 to obtain a high-dimension hidden representation 334. Thereafter, a positional embedding layer 336 is used to obtain the relative position of each token inside the sequence from the physical embedding layer 332.

The hidden representation 312 of the input spectrum, the physical embeddings 332 and the positional embeddings 336 are processed through the decoder blocks 320A through 320N which contain attention layers that are the major working mechanisms behind GPT. The first self-attention layer is a multi-head self-attention layer 322 used to learn the relationship between layered structures. The multi-head self-attention layer 322 receives the physical embeddings 332 and the positional embeddings 336. A second-attention layer, a multi-head cross-attention layer 324, receives the output of the multi-head self-attention layer 322 and the hidden representation 312. The multi-head cross-attention layer 324 captures the relationship between the input spectrum and the multilayer structure. A forward-layer 326 provides the output of the multi-head cross-attention layer 324 to the next decoder block 320B. The series of decoder blocks ultimately provides the probability output 242 from the last decoder block 320N. The probability output 242 a probability distribution over all tokens. The model 226 is trained for approximately 200 epochs based on “next-word prediction” using this probability output.

Referring now to FIG. 3B, a large training dataset 340 with 10 million samples and a validation dataset with 1 million samples is used to train the transformer 224. The total number of datasets is only about 1/10\hat{ }52 of the possible structures. Each sample is a pair of a randomly sampled multilayer thin film structures on a glass substrate and the corresponding spectra simulated using Transfer Matrix Methods (TMM). The training set has a refraction of index for different materials and the thicknesses of the materials. Details of training and model architecture are provided below. Once trained, the model 226 uses input spectra target 342 to provide multi-layer optical structures 344.

Referring now to FIG. 3C, the model 226 and transformer 224 finish the design layer-by-layer in an auto-regressive method. That is, the same transformer 224 is illustrated performing a material and thickness determination for each layer. The target spectrum 240 is provided to each iteration together with the output tokens 350 of the previous layer. The probability outputs 242 are illustrated in graph form, in this example. The probability output 242 and a layer output have structure tokens 352 in a structure sequence that corresponds to the material and thickness of the layers.

In summary, when designing the iₜₕ layer, the model 226 takes in the target spectrum 240 together with the structure sequence of the previously designed i−1 tokens 350, and outputs a probability distribution output 242 for all 900+1 tokens. Sampling from this distribution gives the design at the iₜₕ layer. The tokens 352 of the sequence structure will again be used as the input tokens 350 when designing the i+1ₜₕ layer. The design process will keep going until reaching the maximum layer such as 20, in this example, or the end of sequence (EoS) is sampled.

The probability sampling has many advantages. First, because of the randomness during sampling, running each separate design process can output different structures. Therefore, the method inherently introduces diversity in the designed structure, capable of output multiple structures that satisfy the design target. In addition, it enables the model to design structures with different number of layers. For example, when ‘EoS’ is sampled at the fifth layer, the model 226 terminates the design process and outputs the existing four-layer structure. The probability sampling will also be used to handle design with constraints as described below. The process in FIG. 3C may be performed many times, each with different results which may be processed as described below.

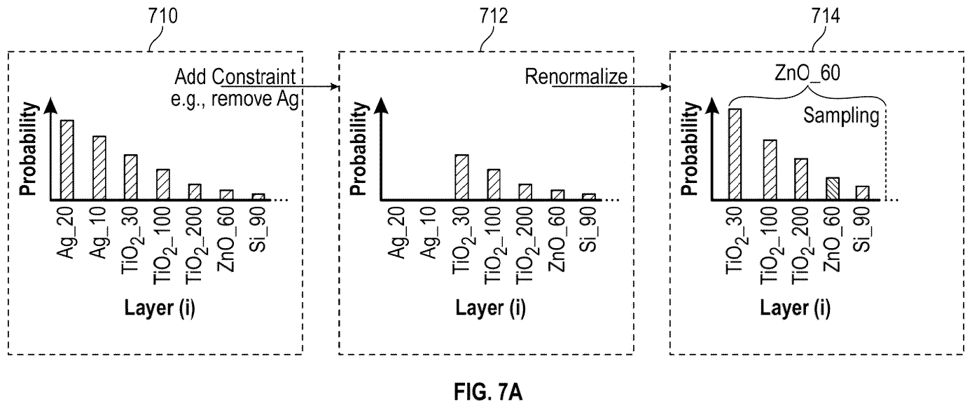

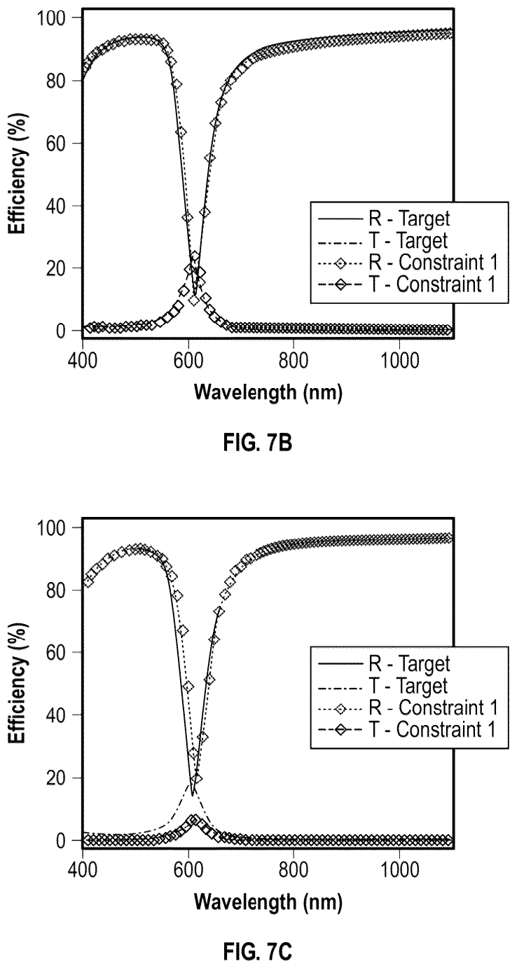

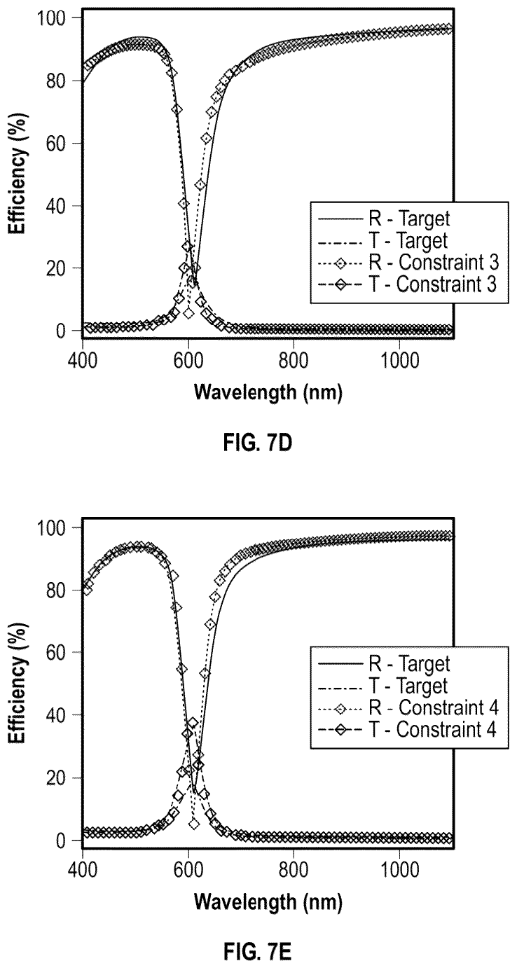

The process of FIG. 3C may also be repeated with different constraints added. That is, a sequence structure may be obtained. The obtained sequence structure and a constraint may be provided to the transformer to obtain a revised sequence structure of tokens. The use of constraints on previously generated sequence structures is described in greater detail in FIG. 7A below. This situation is useful because oftentimes in a design process little is known until an initial design is obtained.

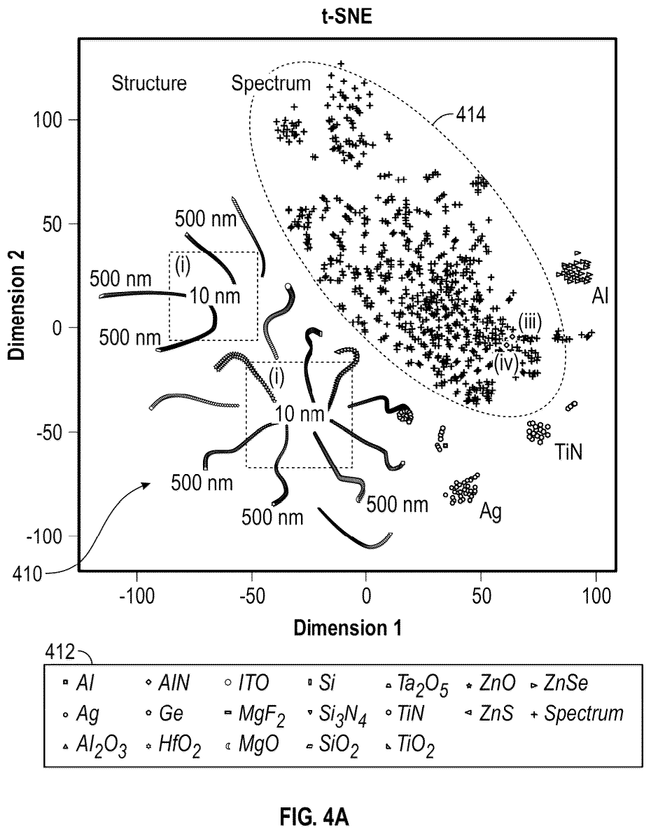

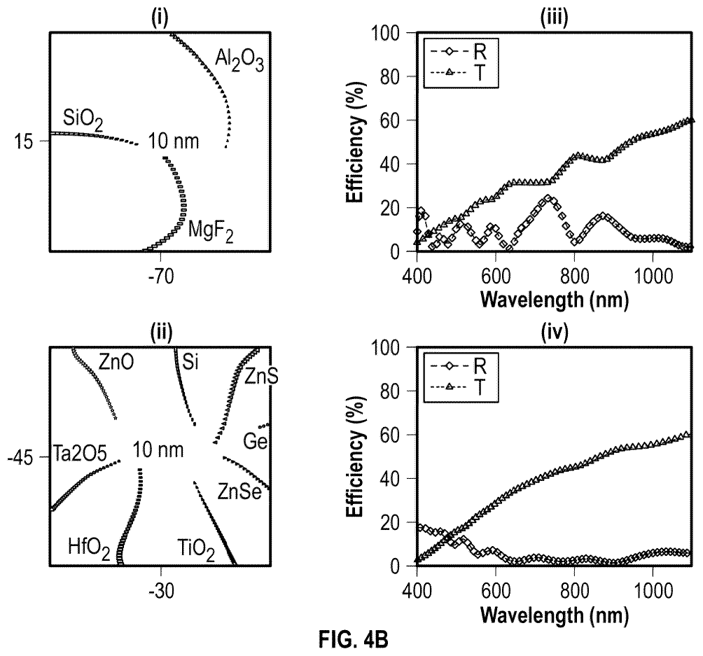

Referring now to FIGS. 4A and 4B, it is instructive to examine if the proposed structure tokens can capture the material and thickness information. A t-distributed stochastic neighbor embedding (t-SNE) is used to reduce the dimension of the physical embeddings to 2-dimensions and visualize results. To further compare the embeddings with the spectrum input, 1,000 spectra were randomly selected from the validation dataset to visualize the dimension reduction results of the hidden representations. Several interesting features are immediately observed. First, the physical structures (traces 410 consisting of individual dots representing the structure tokens 412) and optical spectra responses (cluster encircled by boundary 414) are well separated in this 2-D representation, even though they were fed into training on the equal footing. This demonstrates that the model 226 has learned to distinguish the attributes of material structures and optical spectra while mapping them into the same hidden representation space.

Second, the 900 structure tokens are easily distinguishable, either as curves (the starting and ending points correspond to thickness of 500 nm and 10 nm respectively), or cluster of dots, with no overlap between different materials. Upon close examination, it is clear that the model 226 has intelligently separated the low refractive index dielectrics from the high refractive dielectrics (in the zoom-in view in (i) and (ii) of FIG. 4B). Within these two groups, all curves converge to the center region representing the lowest thickness of 10 nm. This is anticipated from optical physics: when the dielectric layer thickness is reduced to minimal, all materials will behave similarly as they contribute to negligible optical phase change or optical absorption (in the case of high index material). In other words, the model has learned that thin dielectric layers of different materials all have similar effect on light propagation in multilayer thin films. Equally interesting is that all the metals cluster into their own territories in this 2-D map. This can be understood because as the metal layer thickness is greater than the optical penetration depth, its contribution to the optical response (i.e. spectra) has little dependence on the thicknesses. These observations demonstrate that even though the model does not directly take in any refractive index nor thickness, it can capture this information and learning hidden representations from a large dataset, validating the usage of structure serialization and spectrum embedding. This also aligns well with the strong representation capabilities demonstrated in many other foundation models such as Galactica27, GaTo28, and PaLM-E29.

FIGS. 4A and 4B specifically show a two-dimensional visualization of the hidden space using t-SNE to reduce dimension. 900 structure tokens and 1,000 spectra are randomly selected from the validation dataset. Spectra are marked and structure tokens are dots corresponding to different materials. The circle illustrates the approximate boundary 414 between spectra and structures. Inside this boundary are the spectra, with examples of two different spectra given in FIG. 4B (iii) and (iv). Outside the boundary 414 are structure tokens corresponding to different material and thickness combinations. These structure tokens with the same materials either form a line shape or cluster together. For each line, the dot size is monotonically decreasing from one end to the other end, corresponding to the monotonical thickness decrease from 500 nm to 10 nm. Most lines converge into two regions, with zoom-in details given in FIG. 4B at (i) and (ii) corresponding to low refractive and high refractive index regions, respectively. The model 226 demonstrates the ability of learning the material and thickness from a large dataset without their explicit inputs.

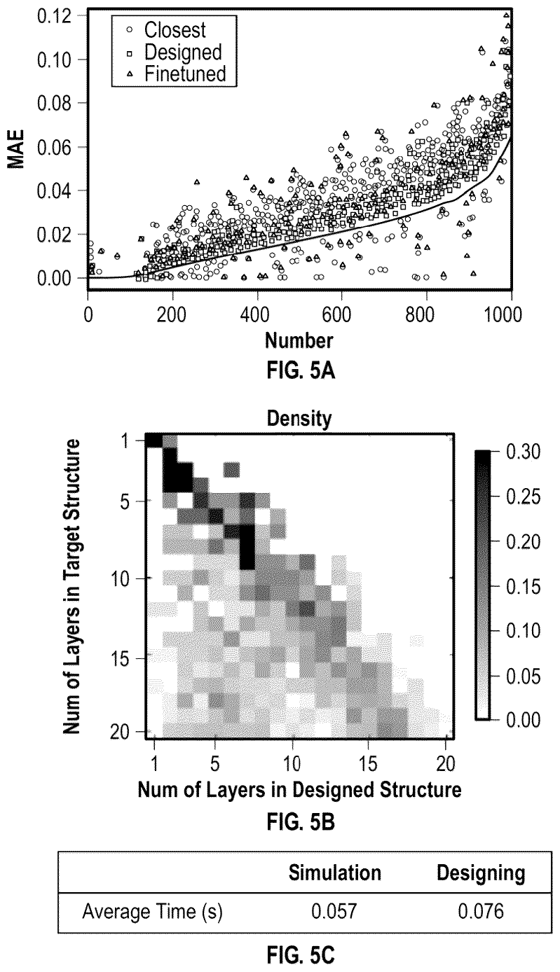

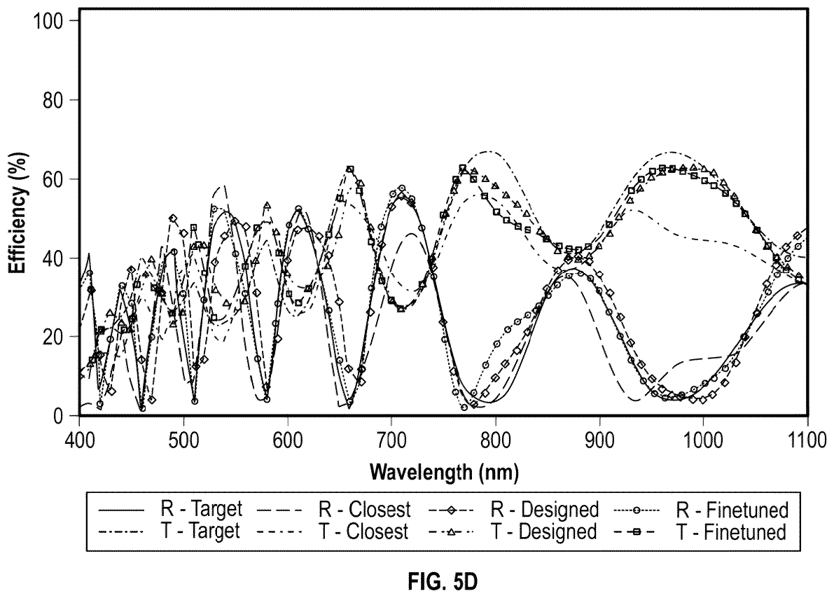

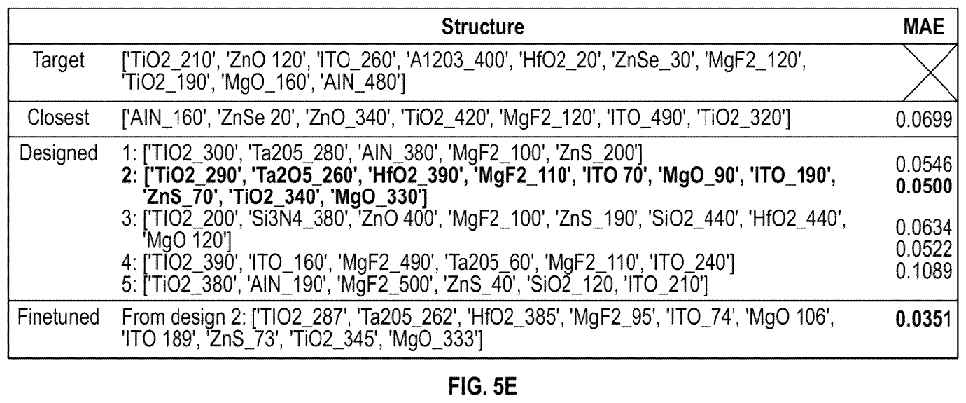

Referring now to FIGS. 5A-5E, the inverse design performance on different application situations is described. In use, the model 226 is static after training and all the design tasks can be finished nearly instantaneously by feeding different inputs of target optical response into the model. However, in case of higher accuracy is required, a thickness finetuning to improve the performance because the 10 nm discretization of thickness may lead to sub-optimal performance for certain materials (e.g. metals and absorbing dielectrics). By default, the design performance without thickness finetuning is provided unless specified.

The averaged inverse design performance on 1,000 spectra targets randomly selected from the validation dataset is evaluated. Based on the multilayer design output from the model 226, the corresponding spectrum is simulated using TMM and the Mean Absolute Error (MAE) is calculated between the input spectrum and the simulated spectrum to quantify the design accuracy. The closest spectrum with smallest MAE in the training dataset is treated as the design baseline, i.e., the best spectrum by simply referring to the training dataset. A good machine learning model should be able to learn from and outperform the training dataset. FIG. 5A shows a comparison of the MAEs of the closest structures in the training dataset, designed structures, and finetuned structures. On average, the MAE of the designed structures is 0.0258, which is lower than the MAE of the closest structures (0.0296) in the training set; finetuning the thickness can further reduce the MAE to 0.0192 (about a 24% reduction). In FIG. 5B, the number of layers in the target structure (the structure corresponding to the target spectrum in the validation dataset) are compared to the number of layers in the designed structure. The zero upper diagonal matrix implies that the model learns to solve design tasks using a simplified structure with fewer layers (approximately 6 layers on average), which can facilitate the fabrication process as structures with fewer layers are easier to make. The time-consumption is set forth in FIG. 5C. On average, the model completes each design within 0.1 s, which is comparable to running a TMM simulation. One inverse design example is shown in FIGS. 5D and 5E. By running the sampling process multiple times, the model 226 outputs multiple different structures with close-to-target spectrum that are much better than the training dataset. The designed structures also illustrate the diversity in FIGS. 5D and E.

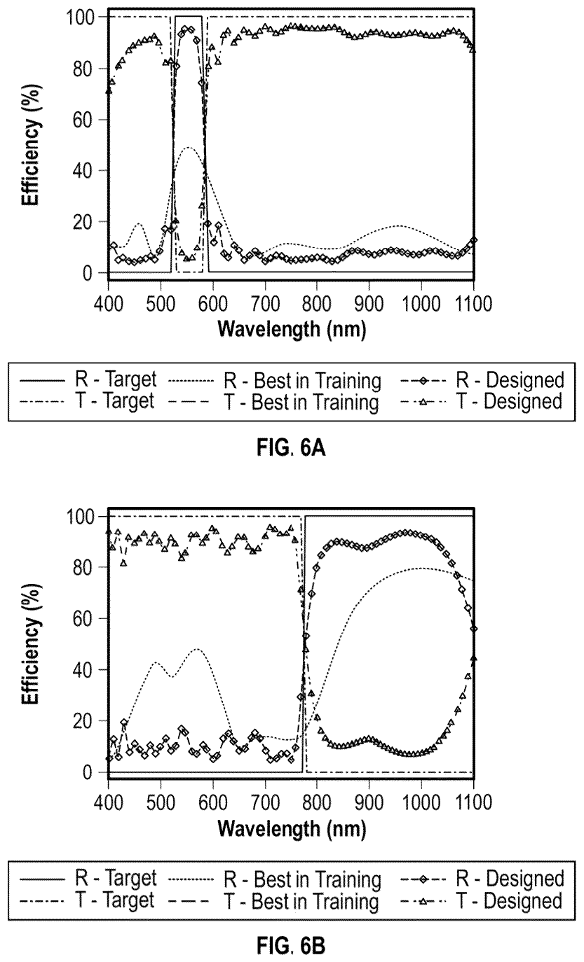

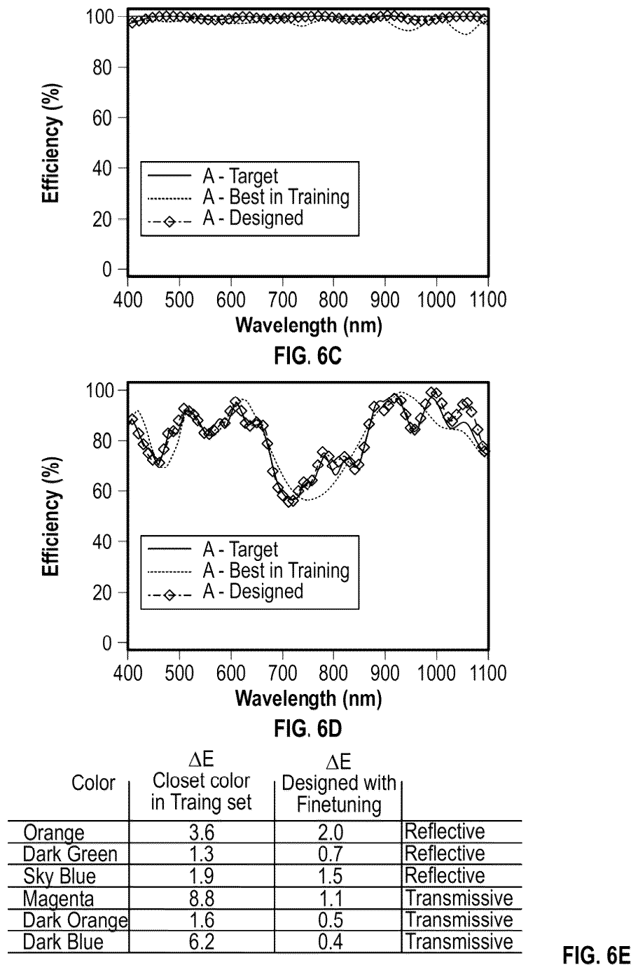

Referring now to FIGS. 6A-6D, the model 226 is evaluated based on practical inverse design tasks. One such application is a spectrum filter which is used to selectively reflect or transmit specific bands of light. Many deep learning-based methods have been proposed to inverse design these filters. Here, several examples are tested: a band-notch filter at 550 nm is shown in FIG. 6A, a band-notch filter at 700 nm, a high reflection in NIR is shown in FIG. 6B, double high reflection in 500-600 nm and 800-1000 nm. The input is set to be the perfect rectangular spectrum, which has 0% transmission in the desired region and 100% transmission in the rest region. In all these artificial spectrum design targets, the model can output designs that outperform the training dataset. Thickness finetuning can further improve the accuracy. Two examples are shown and compared with the respective spectrums in FIGS. 6A and 6B.

In FIGS. 6C and 6D, a perfect absorber and an arbitrary absorber are illustrated respectively. Perfect absorbers have been widely used in photovoltaics, radiative cooling, detecting and solar-thermal harvesting, etc. Although the model is trained on reflection and transmission spectrum, it also demonstrates good performance for perfect absorbers. This is done by simply setting the input spectrum as zero for both reflection and transmission. The model gives multiple designs, one design of which is shown in FIG. 6C.

Apart from perfect absorbers, the model can also be designed for arbitrary absorption. Since energy conservation guarantees that reflection+transmission+absorption=1, the input spectrum may be tailored by setting reflection to be one minus absorption and setting transmission to be zero as shown in FIG. 6D.

Compared to dyes and chemical pigments, structural colors exhibit unique advantages on high resolution, stability and sustainability and have been widely used in color printing, information encryption, sensors, etc. Deep learning has been used to solve the structural color inverse design. Usually, colors can be represented by a three-dimensional color coordinate, e.g., LAB, RGB or xyY values. In order to make the model well suited for this application, an algorithm that can convert a color coordinate into a continuous spectrum is described below in a generalized way. The converted spectra can be pre-calculated and will not impact the design process. When designing for reflective color, the reflection spectrum is set to be the converted spectrum and transmission spectrum to be zero. For transmissive color, the transmission spectrum to be this converted spectrum and reflection spectrum is set to be one minus transmission. A color difference of ΔE is used to evaluate the design performance (smaller ΔE means smaller color difference). A table is set forth in FIG. 6E for a number of colors, ΔE of the closest color in the training dataset, and ΔE of a designed color from the model (with thickness finetuning), respectively was evaluated. As is shown, the ΔE is much lower using the models for each of the colors and, in some cases, significantly. The first three colors are reflective and the second three are transmissive.

Referring now to FIGS. 7A-7E, a visualization of the design process when adding design constraints is set forth. The example of “remove Ag from material selection at ith layer” is used. A first probability distribution 710 is the initial probability distribution and corresponds to a structure sequence. A second probability distribution 712 is illustrated with the Ag removed to obtain a second structure sequence. A renormalized probability distribution 714 is illustrated When designing the desired ith layer, the tokens that contains “Ag” such as “Ag_10”, “Ag_20”, in this example, are removed that do not satisfy constraints from probability distribution and only sample from the renormalized probability based on remaining tokens.

As an example, an FP resonator design using different constraints is set forth. Here, the target spectrum has a resonance absorption at 610 nm and corresponds to an initial structure sequence of three-layers: 20 nm Ag; 50 nm SiO2 and 50 nm Ag. The layers are used as a resonator on a glass substrate. Different constraints to design an FP resonator may be used. That is, an initial structure sequence may be processed through the transformer 224 and model 226 with an input of a constraint as physical and positional embeddings to obtain a second or subsequent design.

Constraints may be used for many purposes. Researchers may allow the system to generate an initial structural sequence and then limit the design based on the availability of materials and limitations in processes available to them. Examples of constraints are Constraints 1-4 are “Fix the first layer to be 100 nm SiO2”, “Remove Ag in the third layer”, “Limit the thickness of the first layer inside [10, 150] nm and remove Ag/Al in the first layer”, and “Specify the material arrangement to be a three-layer Ag/Si₃N₄/Ag structure and design the thickness only”, respectively.

The first constraint can be used when a dielectric layer at the air interface is needed for protection. The second constraint is practical when looking for an alternative to replace silver, considering silver is an expensive metal. The third constraint is a general example of adding thickness and material restrictions simultaneously. For the design structure, the spectra in FIG. 7A-7D demonstrate that the model can determine designs that satisfy desired constraints while still providing spectrum performance.

In particular, the fourth constraint specifies the material at each layer and only requires thickness design. This is a traditional design process widely used by human experts and in many optimization-based methods. The design results in FIG. 7E show that given the spectrum target and material arrangements, the model can be used for direct thickness design without iterative optimization. Since this feature does not rely on the target optical response, researchers can quickly examine if certain material combinations can achieve the target spectrum and obtain their corresponding thickness if so.

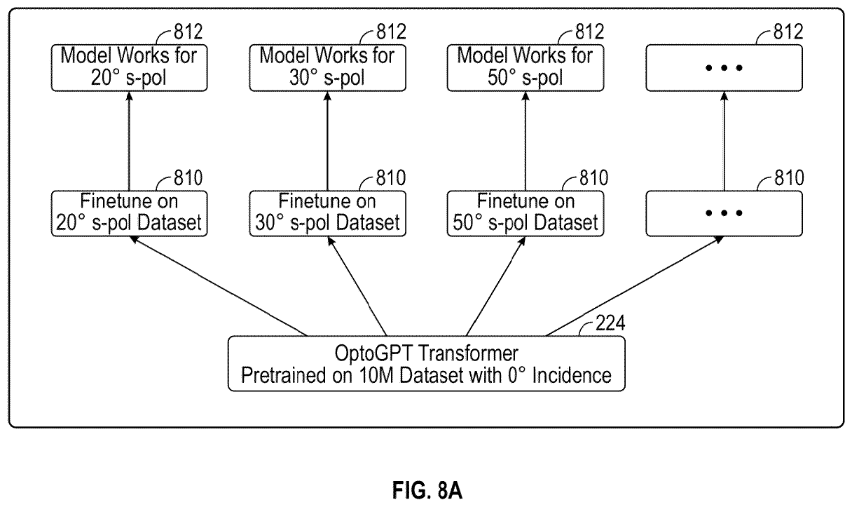

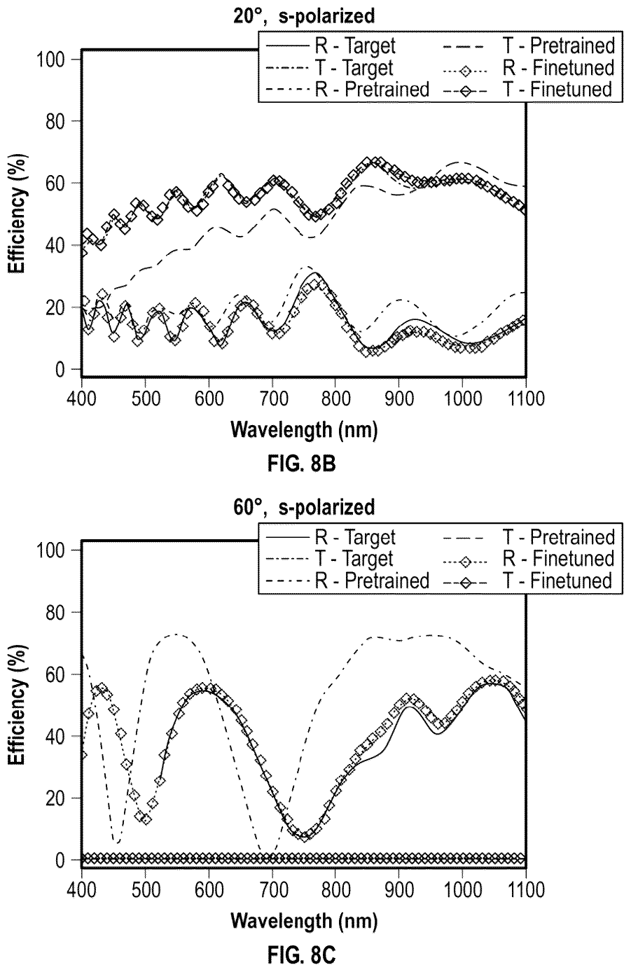

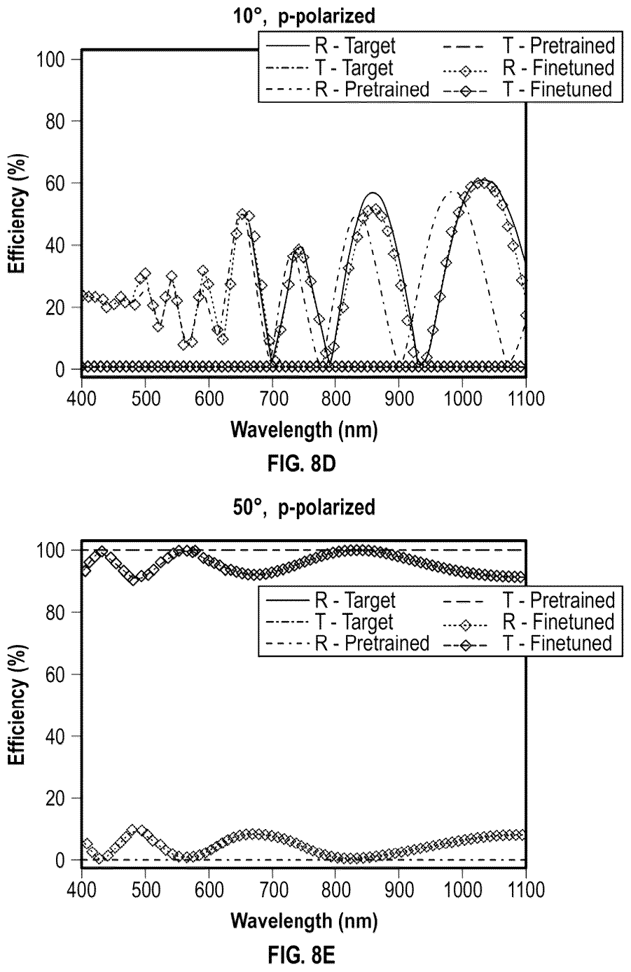

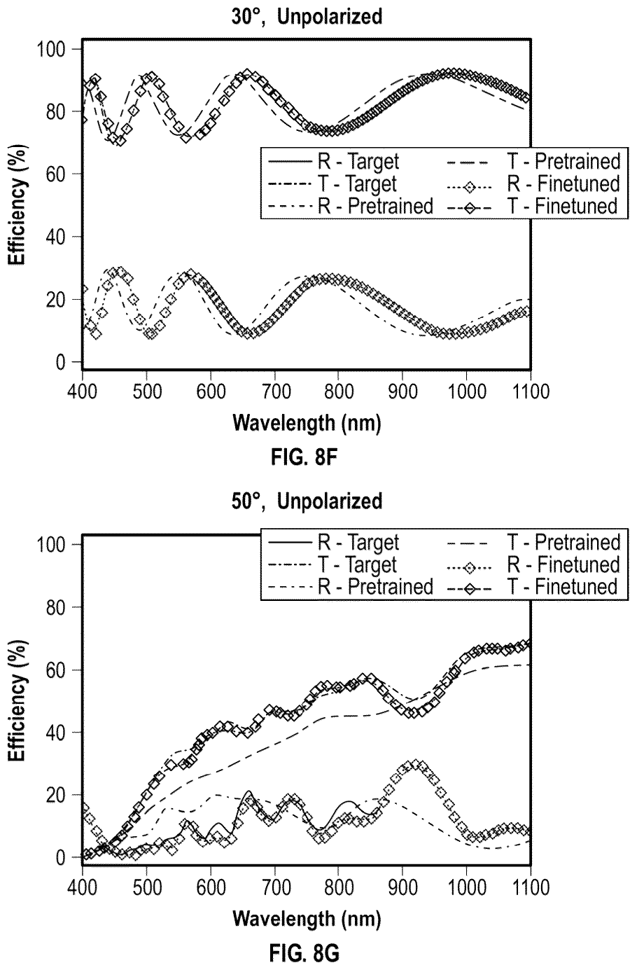

Referring now to FIGS. 8A-8G, although the model is trained on normal incident spectrum, its strong generalization ability enables the design towards different angles of incidence or output angles and polarization states, expanding allowable applications significantly. This is achieved through finetuning the model on a small dataset. Mixed sampling may be used to design structures that satisfy multiple requirements simultaneously.

Starting with the model 226 of the OptoGPT system 210 trained on a 10M dataset, the model 226 may be fine-tuned on a smaller dataset to suit light incidences of different angles, polarization states, direction of light output, or combinations thereof. FIG. 8A gives a finetune diagram. Specific datasets 810 are used to form an updated model at 812. For example, in order to design for s-polarized spectrum under 20° incident angle, a small 1M dataset with such spectrum and then update entire model by 10 epochs at 812. This only requires 1% computing resources compared with training the entire model from scratch. Similar procedures can be done for other angles and polarizations. In FIGS. 8B-8G, inverse design examples finetuned for 20° s-polarization, 60° s-polarization, 10° p-polarization, 50° p-polarization, 30° unpolarized light and 50° unpolarized light, respectively, are illustrated.

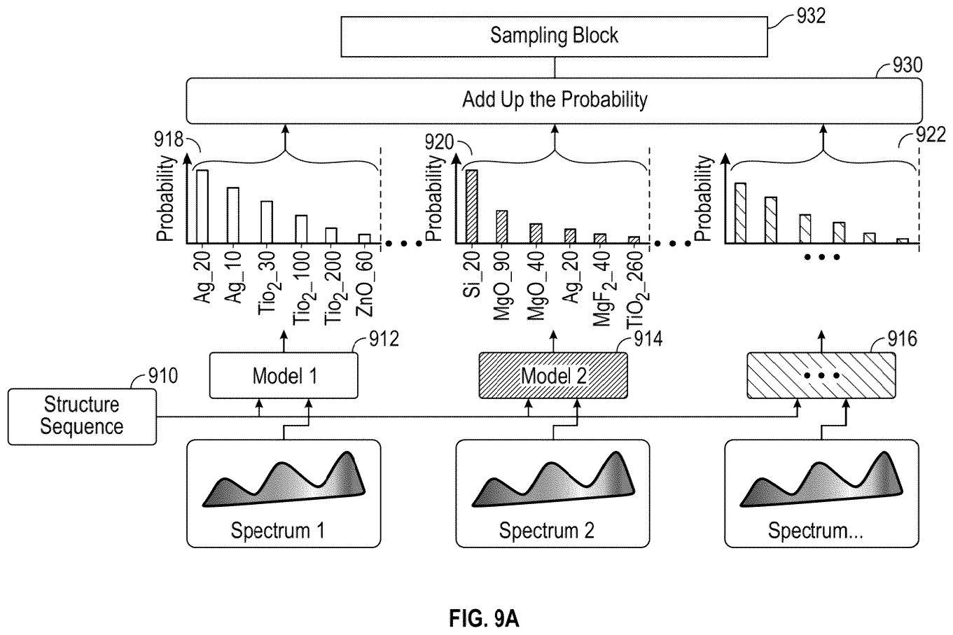

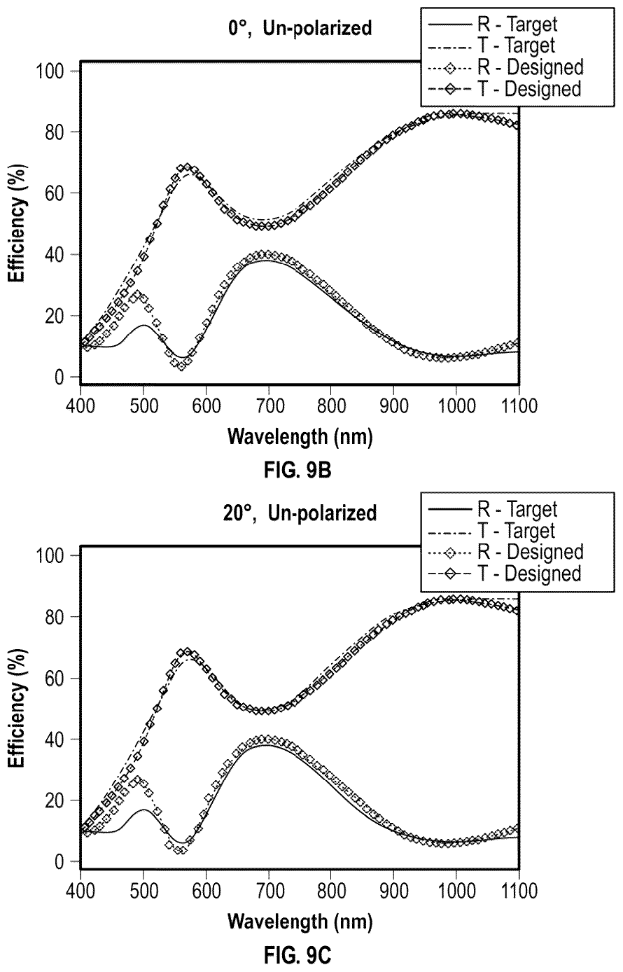

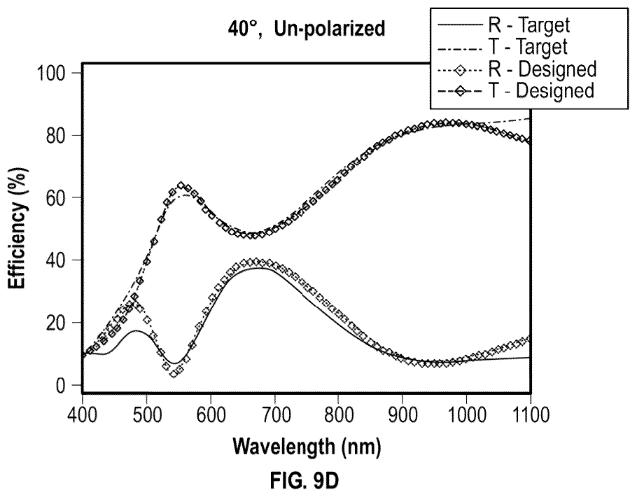

Referring now to FIG. 9A-9D, instead of designing the spectrum for a specific angle of incidence or output/polarization, in some situations a designed structure can simultaneously realize multiple spectrums. A structure sequence 910 is provided to the differently trained models 912-916 that have been trained with different incidence angles, polarizations, or a direction of light output or combinations thereof. The initial sequence structure 910 may be generated using the system of FIG. 3C. Target spectrums 904, 906, 908 with different wavelengths may be provided to differently trained models 912-916. The differently trained models 912-916, based on the spectrums 904-908 and the structure sequence 910 generate a probability output 918-922. The probability outputs 918-922 are provided from each of the models 912-916 and are specific to each specific training. A probability summing block 930 sums the probabilities from each model 912-916. A sampling block 932 samples the probabilities to obtain the layers with the highest probabilities for the layer materials and thicknesses as performed in FIG. 3C in an auto-regressive way. The output of the sampling block 932 is a mixed output. This is called “Mixed Sampling.” The mixed sampling output of layer materials and thicknesses are therefore responsive to multiple polarizations and angles of incidence.

As an example, in FIGS. 9B-9C, a method to design an angle-invariant spectrum at 0°, 20° and 40° for unpolarized light is set forth. The solid line, dashed line and squared line correspond to the target spectrum, the spectrum designed by the pretrained model and the spectrum designed by the finetuned model, respectively.

By converting the multilayer structure into a sequence using structure tokens and structure serialization, the present system effectively deals with the non-trivial inverse design problem in a multilayer structure. Combined with many proposed techniques, the model can unify the inverse design under different types of input targets under different incident angle/polarization/direction of light output, be versatile to different types of structures, as well as facilitating the fabrication process by providing the diversity and flexibility. The development of the OptoGPT system 210 makes the multilayer thin film structure-based inverse design effective in methodology and an easily accessible to researchers and engineers.

The interesting findings of the hidden representations of the OptoGPT system 210 suggest that it has acquired domain-specific knowledge pertaining to optical multilayer structures through the training process. Furthermore, the model has demonstrated the capacity to apply this acquired knowledge effectively in the inverse design process.

In addition, using similar methods, the model can be expanded towards high-dimension complicated photonic structures, e.g., 2D metasurfaces or 3D waveguides, using similar tokenization method in Vision Transformer. However, one limitation is that the present model requires a large dataset for training, which is also a common criticism for many GPT models. For example, ChatGPT is trained on billions of tokens using about 10,000 GPUs, costing about $10M for a single training. In the present disclosure, because of the constraint on computation resources, design problems may be simplified, including using limited types of materials, limited spectrum range, thickness discretization as well as the maximum number of layers that can be designed, all of which can be extended with more computation resources. Despite using a large-scale dataset with 10 million samples for training, it is important to recognize that this dataset only covers a small fraction (10⁵²) of the expansive and complex design space associated with optical multilayer thin film structures. Due to this limitation of its training dataset, the OptoGPT system 210 may fail to find a design that lies outside the boundaries of the sampled design space. Close collaboration across multiple research groups is needed to obtain a better model for a more general and better photonic inverse design that expands to more complicated structures.

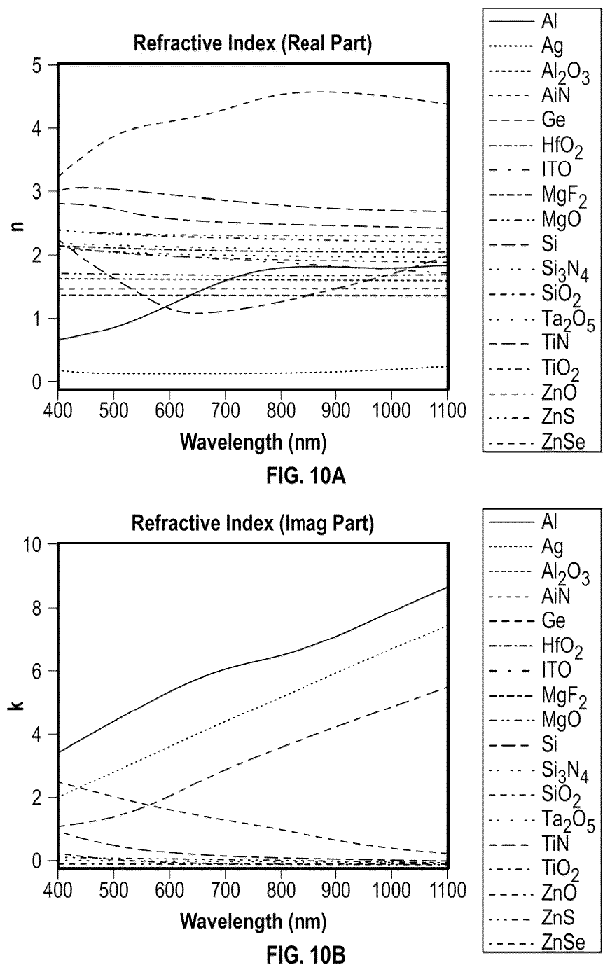

Referring now to FIGS. 10A and 10B, eighteen different materials were selected that are widely accessible in many nanofabrication centers. A single layer was experimentally deposited on silicon substrate and the refractive index was measured using ellipsometer for each sample. The test data may be stored in a test database or dataset generally represented by 340 in FIG. 3B. The refractive index is illustrated, which shows the measured refractive index real part in FIG. 10A and imaginary part in FIG. 10B for all 18 materials. The materials and the refractive indexes are used in the training process.

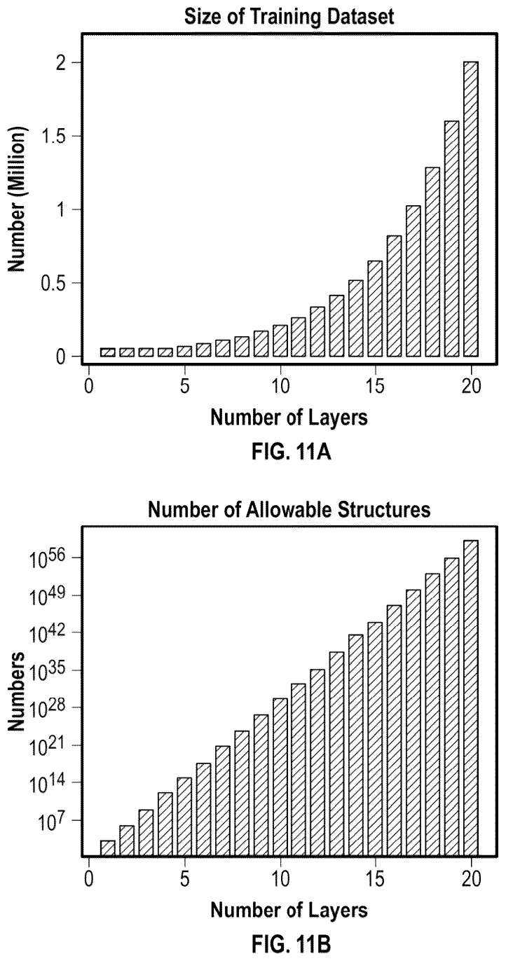

Referring now to FIGS. 11A and 11B, the measured refractive index is used for simulation during training dataset generation. The training dataset and validation dataset consist of 10M and 1M randomly generated samples (glass substrate was used), respectively. Here, the randomness comes from three aspects: material, thickness and the total number of layers. Materials are uniformly sampled from a material database and thickness is also uniformly sampled from 10 nm to 500 nm with 10 nm discretization. In addition, two adjacent layers have different materials. When sampling the total number of layers, considering that the number of possible structures increases exponentially as the total number of layers increases, the number of layers with increasing ratios are sampled. A histogram of the generated samples is plotted based on the number of layers in FIG. 11A. FIG. 11B gives a histogram of the total number of possible structures. FIG. 11A shows a histogram of the number of generated training data with respect to the number of layers. FIG. 11B shows a histogram of the number of allowable structures with respect to the number of layers, which follows an exponential distribution. For a structure with twenty layers, the total number of allowable structures reaches 10⁵⁹.

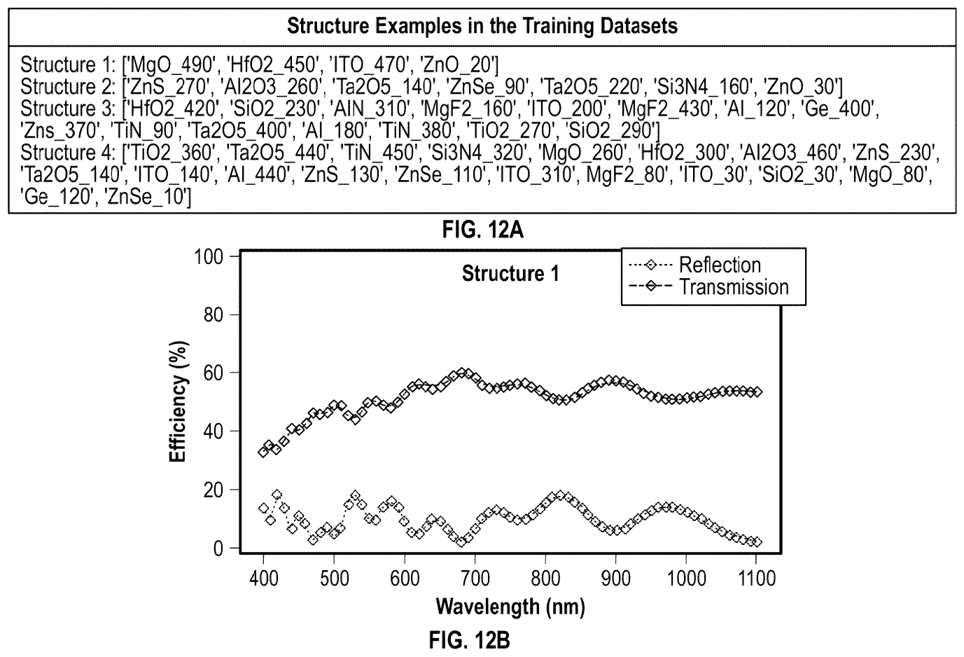

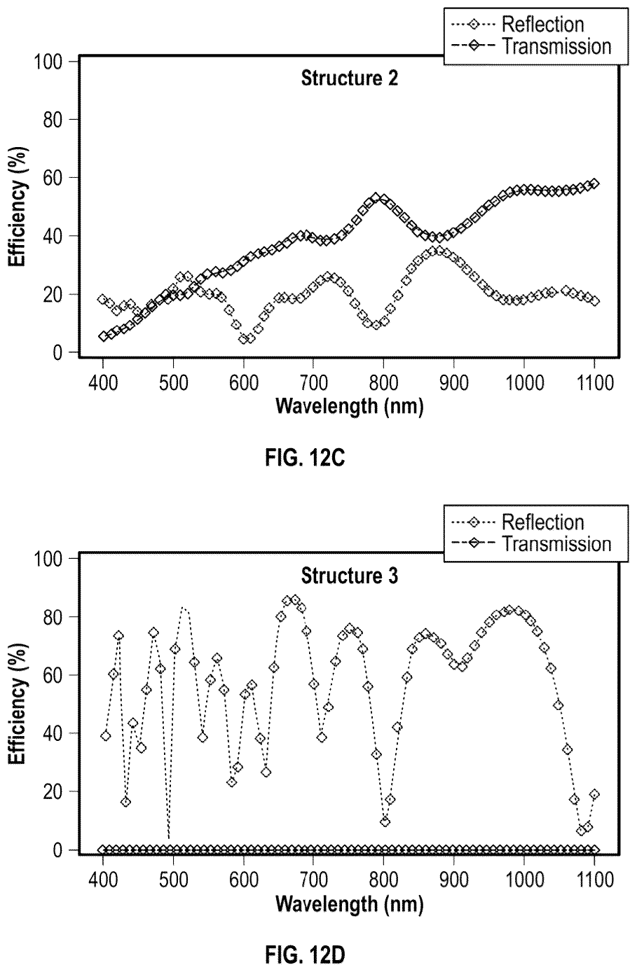

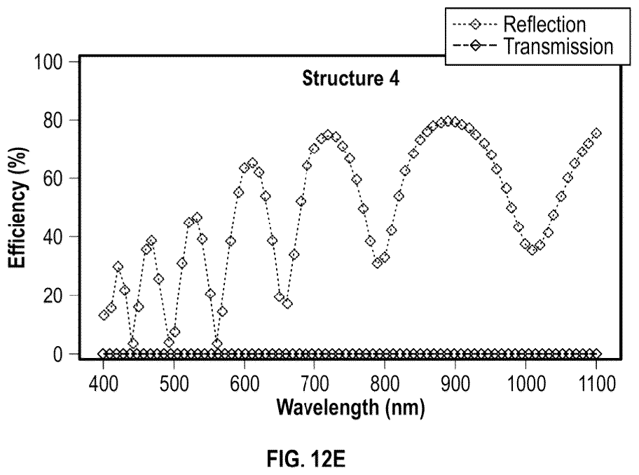

Referring now to FIGS. 12A-12E after the structure is sampled, transfer matrix methods (TMM) are used to simulate the reflection and transmission spectrum. It took about 1200 hours to simulate all 10M structures and can be faster with parallel computing. It also took about 12 GB to store the generated dataset. Four examples of generated structures and simulated spectra are given in FIG. 12A. FIGS. 12B-E four examples in the training dataset are shown. Structures are given in FIG. 12A, and their transmission and reflection spectrum are given in FIGS. 12B-12E.

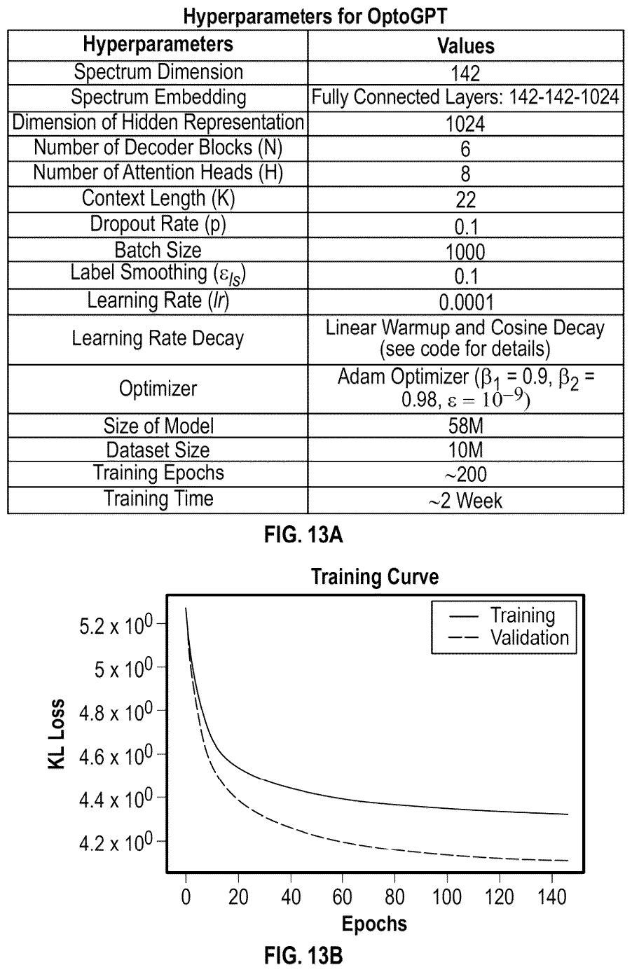

Referring now to FIGS. 13A and 13B, the hyperparameters used in the model architecture are summarized in the table of FIG. 13A. Kullback-Leibler (KL) divergence is used as the training loss, with the goal of recovering the input structures from the probability distribution. During training, an Adam optimizer and warmup procedure is used. The residual dropout and label smoothing are also used to provide regularization during training. The training and validation loss curves are given in FIG. 13B.

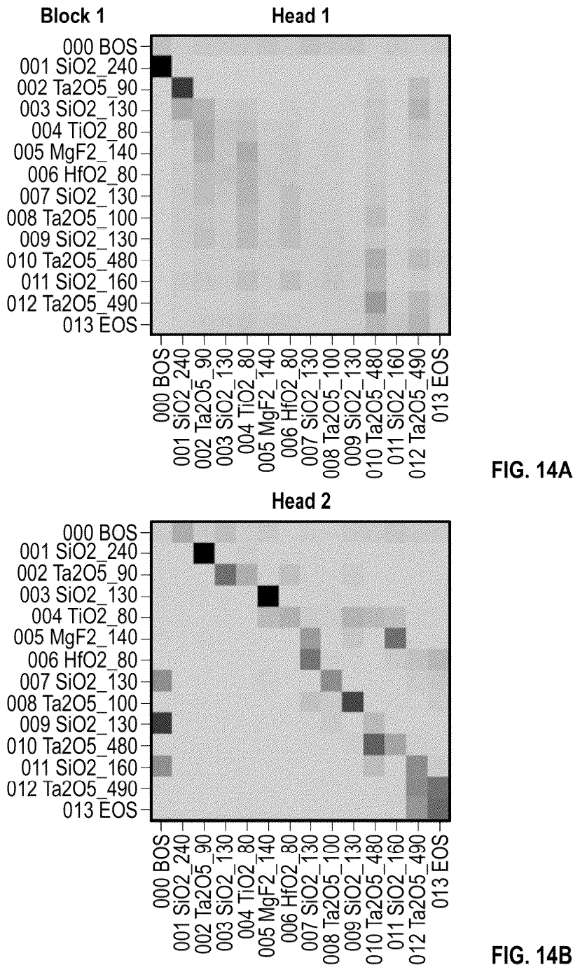

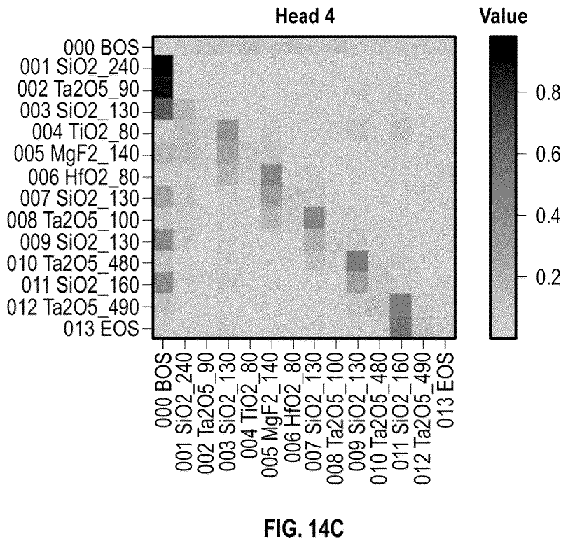

Referring now to FIGS. 14A-14B, when reading, a person usually does not try to memorize all the words inside a sentence. Instead, one selectively focuses on the words that are important to form a basic understanding of the sentence. Self-attention used is a mechanism that relates each single word with all the other words inside the sentence and selectively focuses on several words that are important, similar to how human reads. Multi-head attention allows the model to focus on different aspects. To have a better understanding, FIG. 14A provides a visualization of the attention map for the following structure:

[‘SiO₂_240’, ‘Ta₂O₅_90’, ‘SiO₂_130’, ‘TiO₂_80’, ‘MgF₂_140’, ‘HfO₂_80’, ‘SiO₂_130’, ‘Ta₂O₅_100’, ‘SiO₂_130’, ‘Ta₂O₅_480’, ‘SiO₂_160’, ‘Ta₂O₅_490’]

FIGS. 14A-14C provide a multi-head attention map for the above structure, which has a high-low index profile. The values at each matrix element are their attention with respect to each other tokens (normalized to 1).

The above structure has twelve layers with alternating high-low refractive index profile, similar to the distributed brag reflector (DBR). The attention map is a matrix where each row corresponds to how much attention a single token should be put to other tokens in this sequence. The number of “000” corresponds to the token of “BOS,” which stands for “beginning of sentence” and is a common token placed in front of the sequence of structure tokens and used in many other transformer models. The number of “013” corresponds to the token of “EOS” (end of sentence). Other numbers in front of each token specify its relative position in this multilayer structure. Usually, it is difficult to understand the physical meaning of each attention map because these machine learning models are black-box. Therefore, only attention maps of head 1 (FIG. 14A), head 2 (FIG. 14B), and head 4 (FIG. 14A), in the first decoder block are shown. The attention map for head 2 and head 4 focus more on the layers right below and right above, while head 1 focuses more on the long-term alternating relationship (corresponding to the alternating high-low refractive index profile).

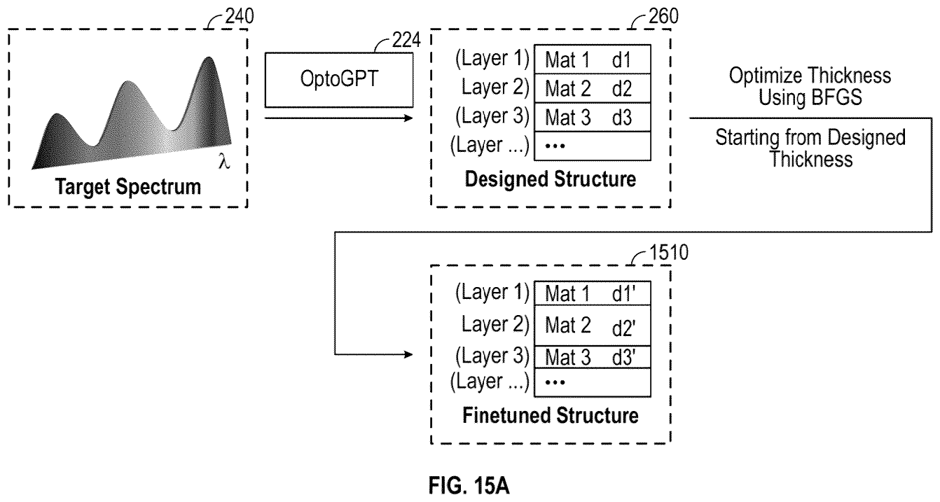

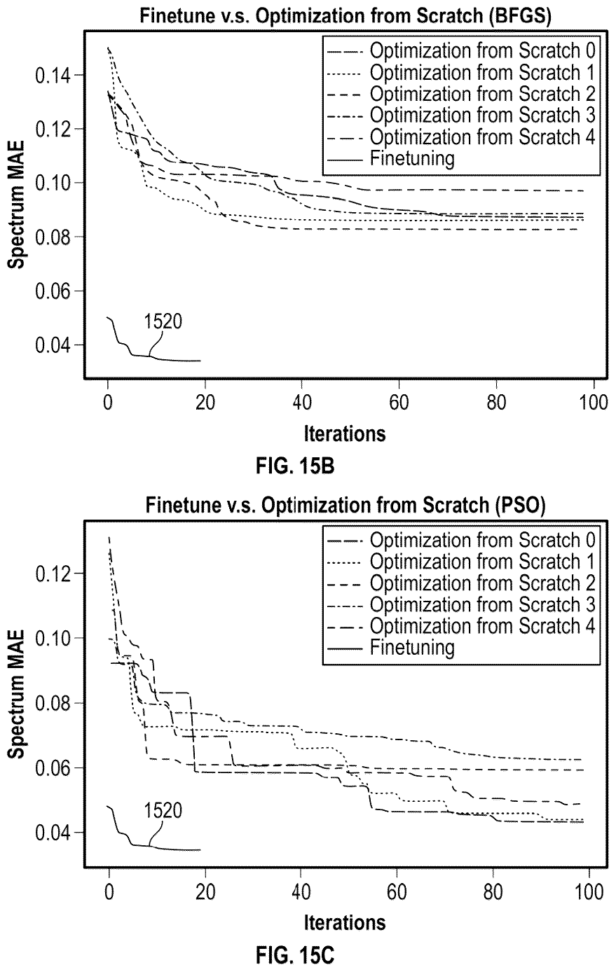

Referring now to FIGS. 15A-15C, during training, the thickness is discretized by a 10 nm gap from 10 nm to 500 nm, so the designed structures 260 from the model and transformer 224 will also have such discretization. A 10 nm gap can be useful for some fabrication tools which cannot guarantee accurate deposition thickness but can be less useful for other tools with high precision deposition, e.g., vacuum deposition. Therefore, a finetuning process is performed, as illustrated in FIG. 15A, by only optimizing the thickness with the goal of minimizing the Mean Absolute Error (MAE) of spectrum. For the structural color application, the visual color difference (denoted as ΔE) is minimized. The limited-memory Broyden-Fletcher-Goldfarb-Shanno (BFGS) method is used to finetune the thickness and use the designed thickness from the model as the optimization starting point. FIG. 15A illustrates details of finetuning the thickness to obtain the fine-tuned structure in 1510. Only the thickness is optimized by setting the designed structure as the starting point for optimization. FIG. 15B illustrates comparing the converge rate of finetuning vs. optimization from scratch using the same limited-memory BFGS method. FIG. 15C illustrates comparing the converge rate of finetuning vs. optimization from scratch using the particle swarm optimization (PSO). Finetuning gives a better performance and is faster (converges within 20 iterations) than designing from scratch.

In FIGS. 15B and 15C, one example of finetuning a structure is given. The finetuning process has the continuous line 1520 in FIGS. 15B and 15C that quickly converges in less than 20 iterations because the model provides a good starting point for optimization. As a comparison, the same optimization algorithm is run from scratch. The optimization task is simplified by using the same materials and only optimizing the thickness. The optimization is run five times by starting from five different random points. Dashed lines in FIG. 15B show results of convergence and spectrum performance at each iteration. None of the five optimizations show better spectrum performance than the finetuning.

Considering that limited-memory Broyden-Fletcher-Goldfarb-Shanno (BFGS) method is a local optimization which depends on the starting points, the finetuning is compared with the particle swarm optimization (PSO), which is an advanced global optimization method. Five different optimizations were also run starting from random initial points. On average, it takes PSO sixty iterations to reach the same performance as the designed structure. None of these optimizations exceed the performance of finetuning. In other words, the design performance of the model is equivalent to running the optimization algorithm at sixty iterations, which saves time and effort.

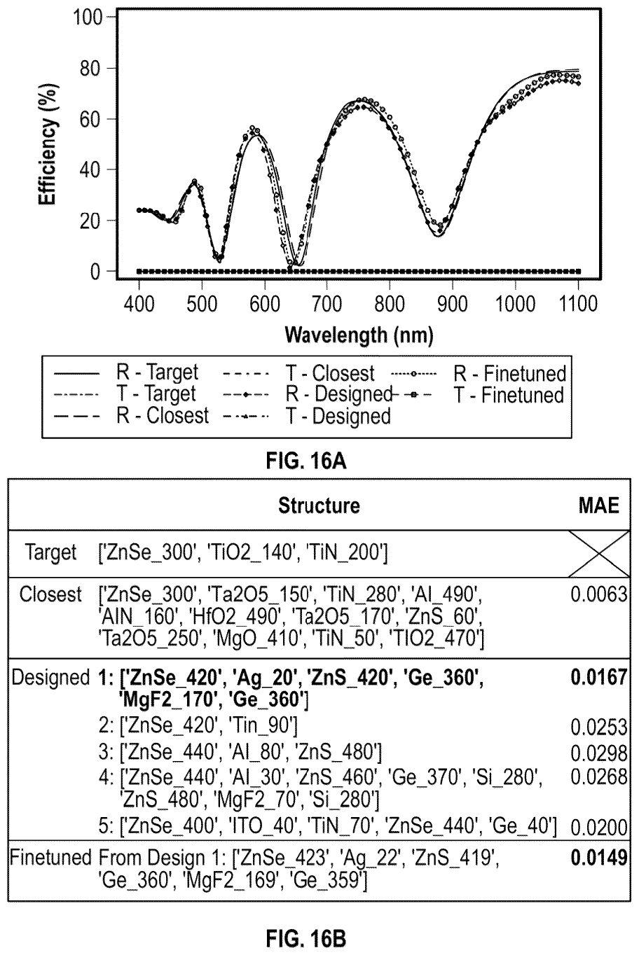

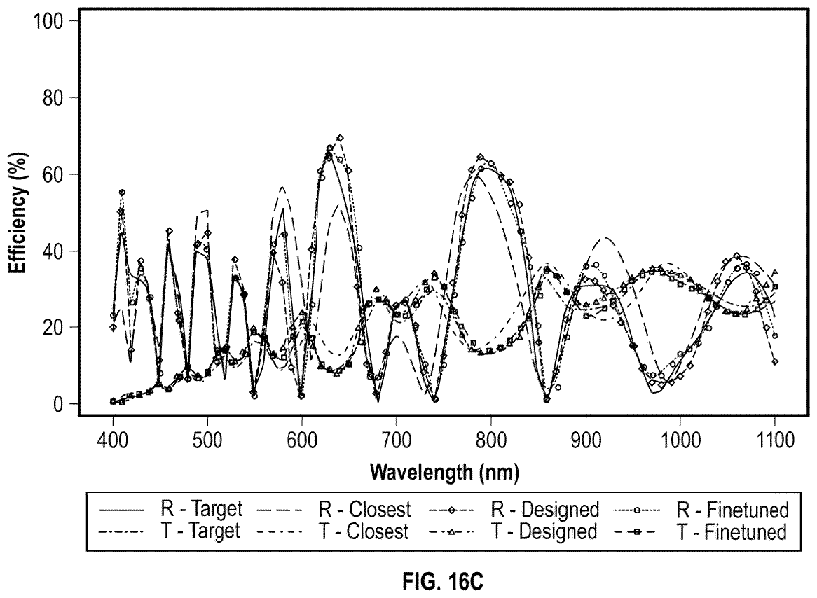

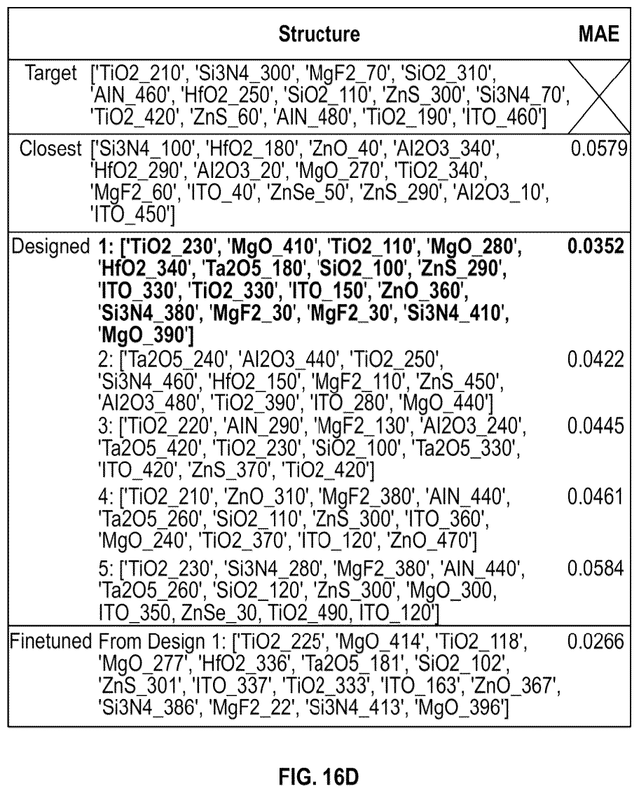

FIGS. 16A-16D provide two more inverse design examples in the validation dataset. In FIG. 16B, the target structure is shown that corresponds to the designed spectrum in the validation dataset, the closest structure in the training dataset, five designed structures and the finetuned structure. The MAE in the last column denotes the spectrum performance. FIGS. 16A and 16C illustrate the spectrum performance and FIGS. 16B and D give the details of designed and finetuned structures.

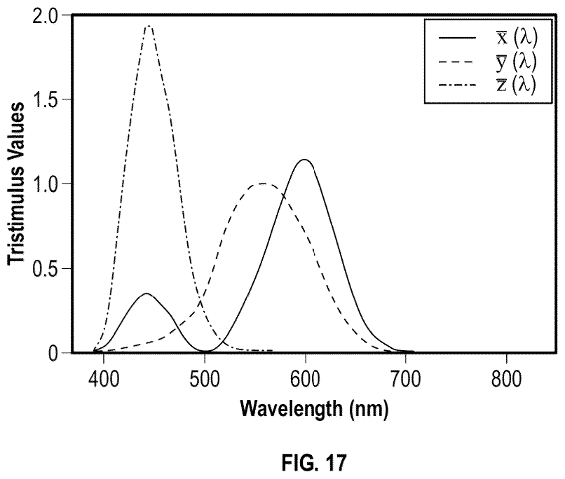

Referring now to FIG. 17, because the target spectrum covers the visible range and near infrared region (400 nm to 1100 nm), it is possible to use the model to design structural color. Here, LAB is selected as the color space. There are many other color spaces including RGB, xyY, XYZ. Those color spaces are not used because LAB space is uniform, which makes it convenient to define the color difference. The ΔE is used to determine the performance of color accuracy. A lower ΔE value indicates greater color accuracy, while a higher ΔE value means a significant color mismatch. Usually, when ΔE<2, it is hard for humans to distinguish the color difference using eyes. During inverse design, the LAB color is first converted to spectrum from 400 nm to 1100 nm, then this spectrum is modified to fit for the model's input. This method can be used to design both transmissive and reflective structural color.

For a given spectrum S(λ), the CIE 1931 XYZ color is first calculated using:

$$X = \frac{1}{K} {\int }_{{λ}_{1}}^{{λ}_{2}} \overline{x} ( λ ) I ( λ ) S ( λ ) d λ$$

$$Y = \frac{1}{K} {\int }_{{λ}_{1}}^{{λ}_{2}} \overline{y} ( λ ) I ( λ ) S ( λ ) d λ$$

$$Z = \frac{1}{K} {\int }_{{λ}_{1}}^{{λ}_{2}} \overline{z} ( λ ) I ( λ ) S ( λ ) d λ$$

where x̅(λ), y̅(λ), z̅(λ) are the color matching functions, I(λ) is the relative spectral power distribution of the illuminating light source (“D65” is used). K is a normalizing factor. The [λ₁, λ₂] is the visible spectrum range and 400 nm-800 nm is used in this case. LAB is then calculated by doing a conversion from XYZ. In FIG. 17 illustrates the color matching functions for “CIE 1931 2 Degree Standard Observer.”

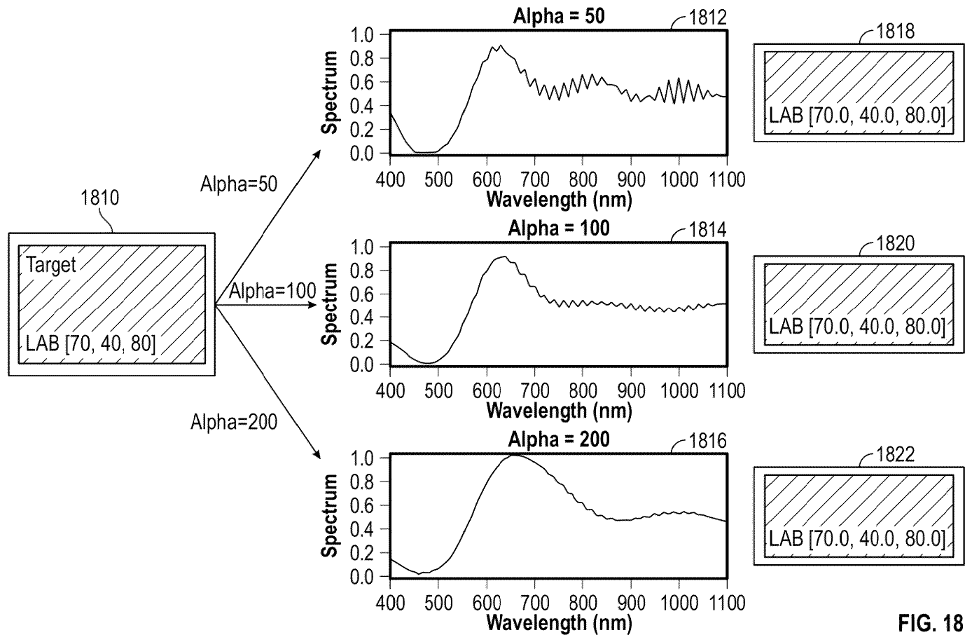

Referring now to FIG. 18, an example of converting a three-dimensional color target LAB_{target}=[a,b,c] 1810, to the 71-dimensional spectrum S=[s_{λ}_{₁}, s_{λ}_{₂}, . . . , s_{λ}_{₇₁}], where λ₁, λ₂, . . . , λ₇₁=400 nm, 410 nm, . . . , 1100 nm is illustrated. This is treated as an optimization task with two different goals. The first goal is to make the color of the spectrum S as close to the target color as possible. The second goal is to make the spectrum to be smooth enough since sudden jump in spectrum is not physical. The particle swarm optimization (PSO) is used to convert color to spectrum S by minimizing the loss:

$$Loss ( S ) = Δ E ( {LAB}_{target} , {LAB}_{S} ) + α * {\sum }_{i = 1}^{71} ( \frac{{d}^{2} S}{{d}^{2} {λ}_{i}} )$$

where LAB_{S} is the color of the converted spectrum. Notice that when calculating color, only the portion of visible wavelength from 400 nm to 800 nm is used. The second term is the second order derivative of spectrum with respect to the wavelength from 400 nm to 1100 nm, which quantifies the smoothness of spectrum. α is a factor that balances the loss of color accuracy and smoothness. In FIG. 18, one example is given of converting yellow color to spectrum under different α factors 50, 100 and 200 at plots 1812, 1814, and 1816. The converted spectrum is less smooth when a is small in plot 1812. FIG. 18 illustrates converting LAB color to spectrum using different alpha factors to obtain outputs 818-822. As alpha increases, the spectrum is smoother.

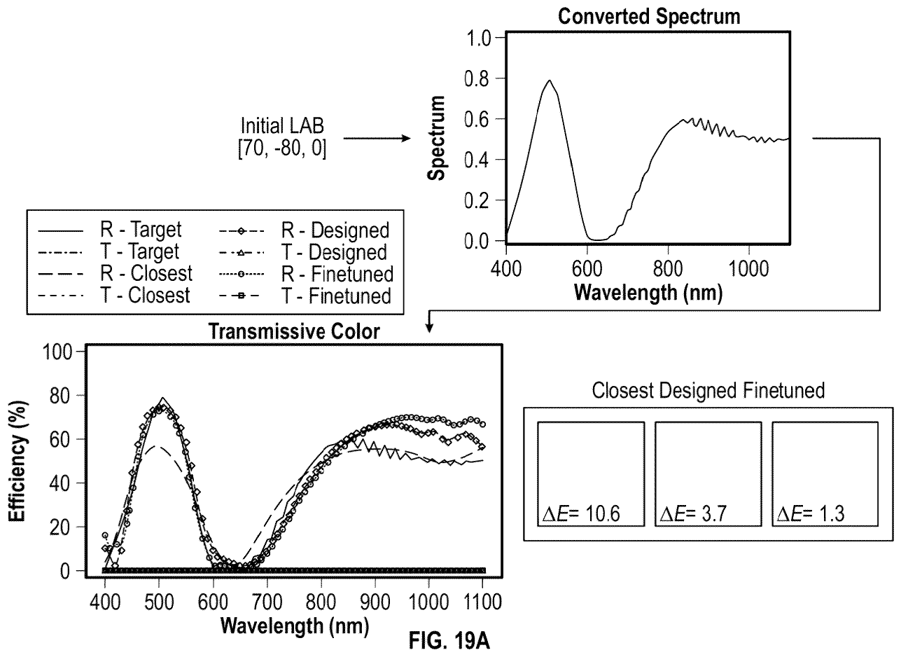

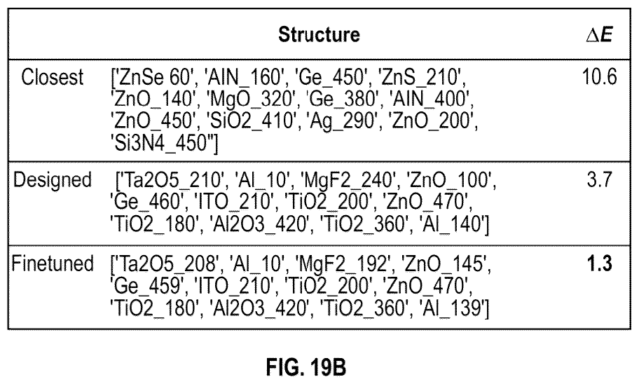

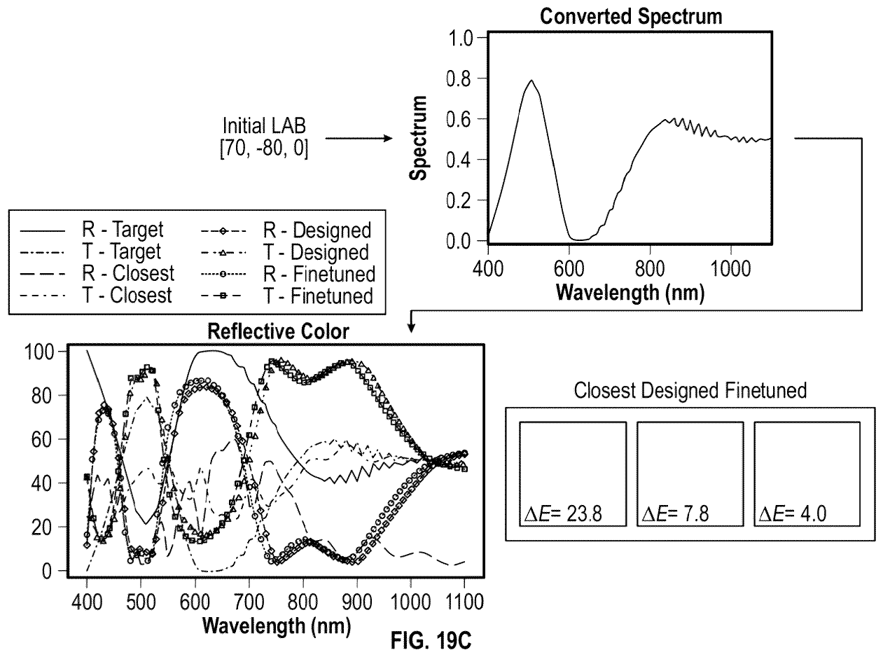

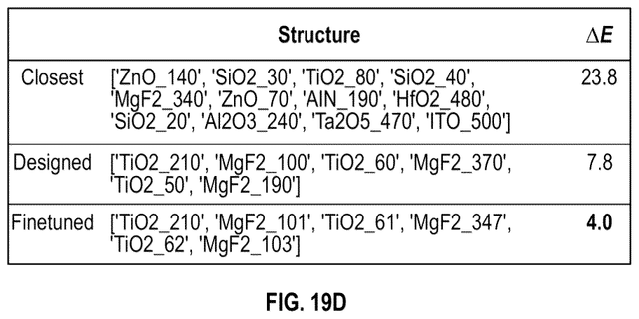

Referring now to FIGS. 19A-19D, two more examples of designing structural color for both reflective type in FIG. 19A and transmissive type FIG. 19C are given. The LAB of the green color target is [70, −80, 0]. First, the converted spectrum is obtained from the LAB value using the optimization algorithm described above. Since the model takes in both reflection and transmission spectrum, extra modification is added to the converted spectrum. In detail, when designing the reflective type, the reflection spectrum is set to be the converted spectrum and the transmission spectrum is set to be 0 (see FIG. 19A). When designing the transmissive type, transmission is set to be the converted spectrum and the reflection spectrum is set to be one minus the transmission spectrum (see FIG. 19C). Finally, the modified reflection and transmission spectrum are fed to the model for inverse design. The spectrum performance and color difference are compared in FIG. 19A and FIG. 19C. The detailed structures of the closest in the dataset, the designed structure and finetuned structure are given in FIG. 19B and FIG. 19D. FIGS. 19C and 19D illustrate more examples of inverse design reflective and transmissive type structure colors.

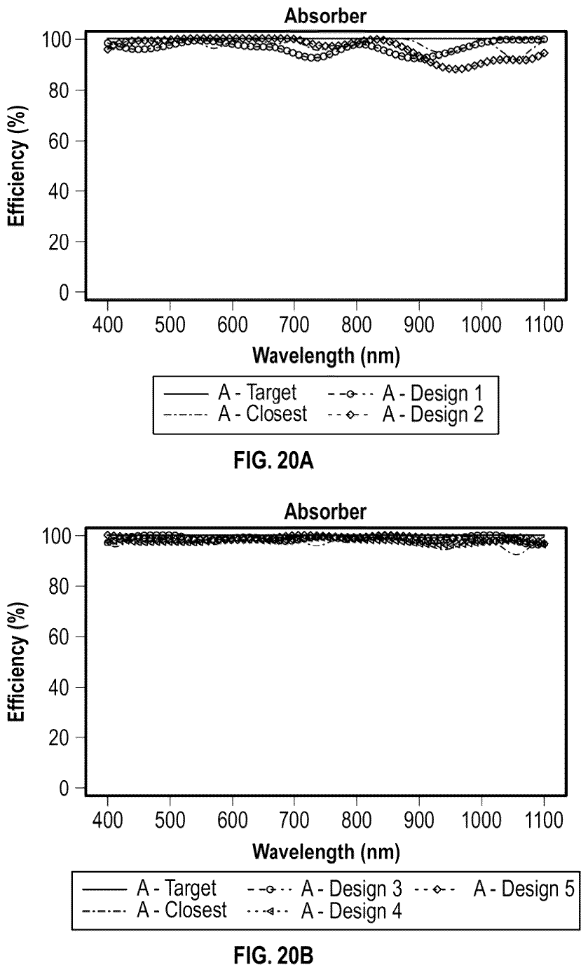

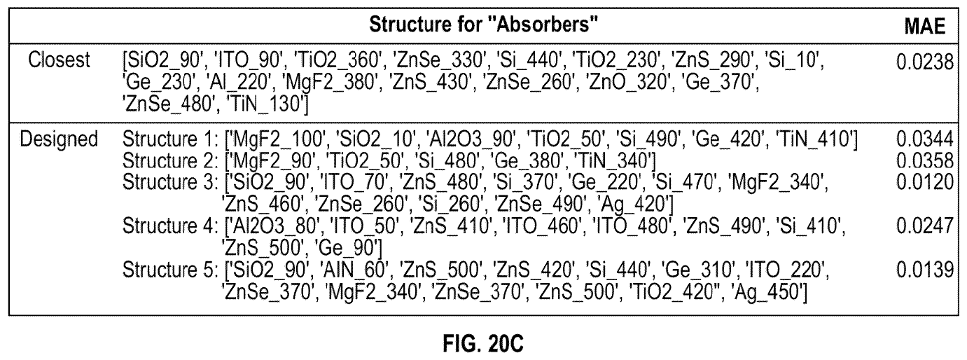

Referring now to FIGS. 20A-20C, more examples of designing perfect absorbers in 400-1100 nm are set forth. To design a perfect absorber, both transmission and reflection are set in the target spectrum to zero. This is because absorption=100%−transmission−reflection, and a perfect absorber requires 100% absorption. Five different designs are shown in FIG. 20C as well as their absorption spectrum in FIGS. 20A and 20B. Their spectra are given in FIG. 19A. This is done by adding a design constraint on the material arrangement in the first several layers discussed above. The designed structure for the perfect absorber in one case is MgF₂ 95.6 nm/SiO₂ 14.7 nm/Al₂O₃ 76.5 nm/TiO₂ 48.0 nm/Si 14.2 nm/Ge 12.0 nm/Ti. The designed structure for the perfect absorber in another case is MgF₂ 118 nm/TiO₂ 56 nm/Si 32 nm/Ge 33 nm/Cr 200 nm/Glass. Even though the 1) materials being used may have different refractive index, 2) Ti or Cr are not in the material and 3) only spectrum inside 400-1100 nm is used, the model can still give similar thickness design for the layers with common materials. In FIG. 20B, the design 3-5 actually exhibits better absorption performance (about 98% absorption on average) than design 1 and 2 in 400-1100 nm. It seems like the structures do not follow the design of graded-refractive index thin dielectric layers on the metallic mirror. FIGS. 20A-20C illustrate examples of inverse design perfect absorbers in 400-1100 nm. Five more designs are given, with spectrum comparisons shown in FIGS. 20A and 20B and structures shown in FIG. 20C.

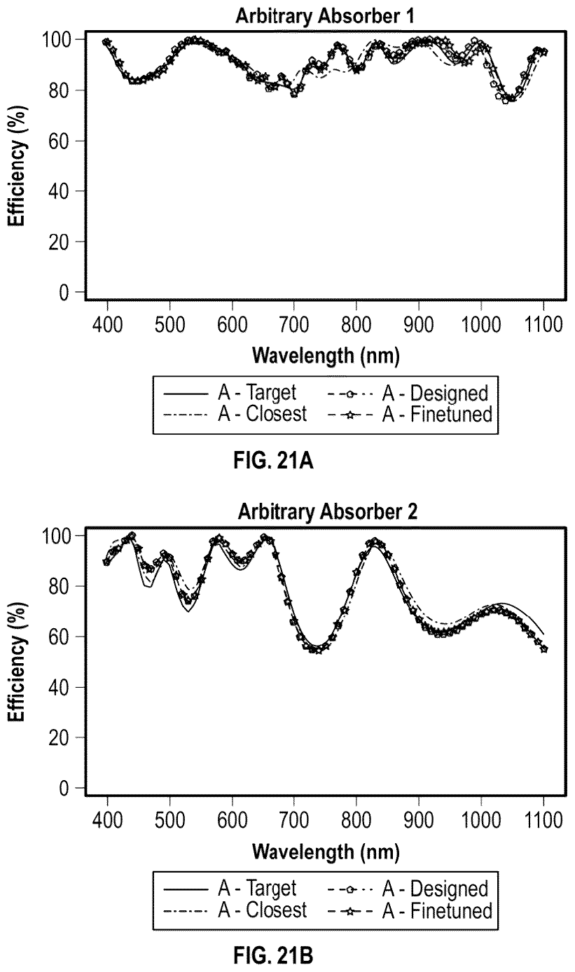

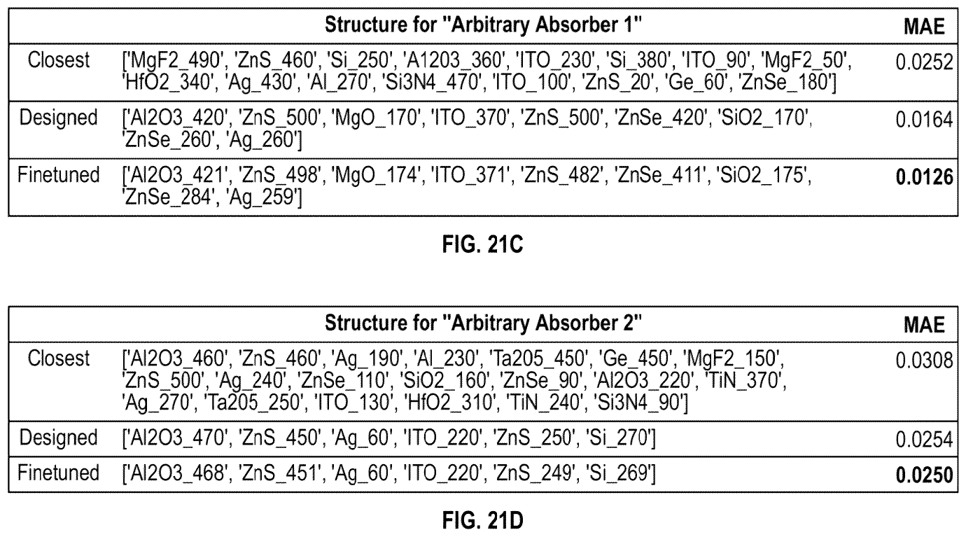

Referring now to FIGS. 21A-21D, the model 226 can be used to design arbitrary absorbers. The target arbitrary absorption spectrum is randomly selected from the validation dataset, by doing a calculation of absorption=100%−transmission−reflection. When converting this arbitrary absorption spectrum to the model input, the target transmission spectrum is set to be zero and target reflection=100%−target absorption. Two examples of arbitrary absorber are given. Their spectra are illustrated in FIGS. 21A and 21B, and the designed and finetuned structures are given in FIGS. 21C and 21D. FIGS. 21A-21D illustrate two examples of design arbitrary absorbers in 400-1100 nm. The spectrum performance is given in FIGS. 21A and 21B, and structures are given in FIGS. 21C and 21D, respectively.

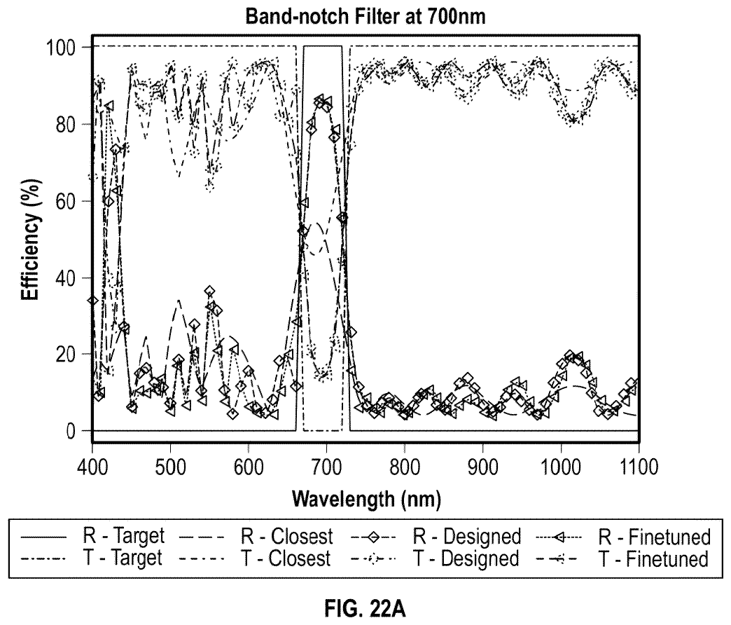

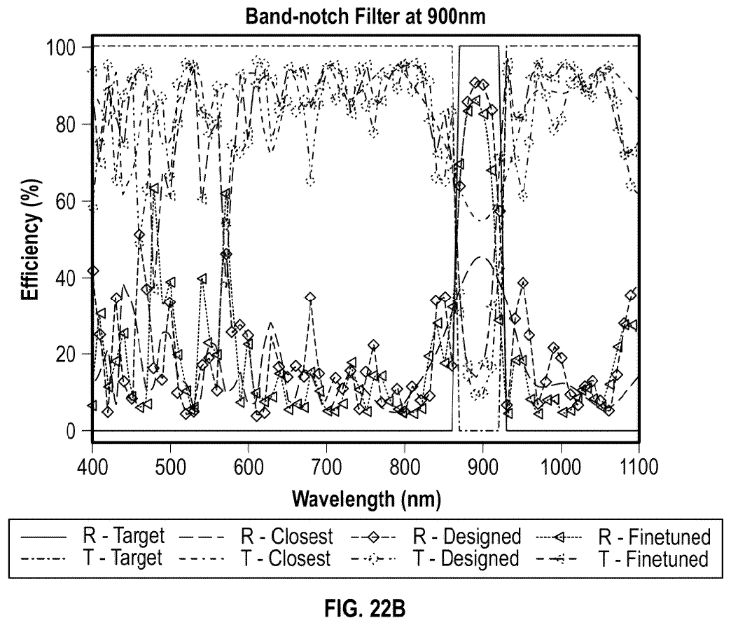

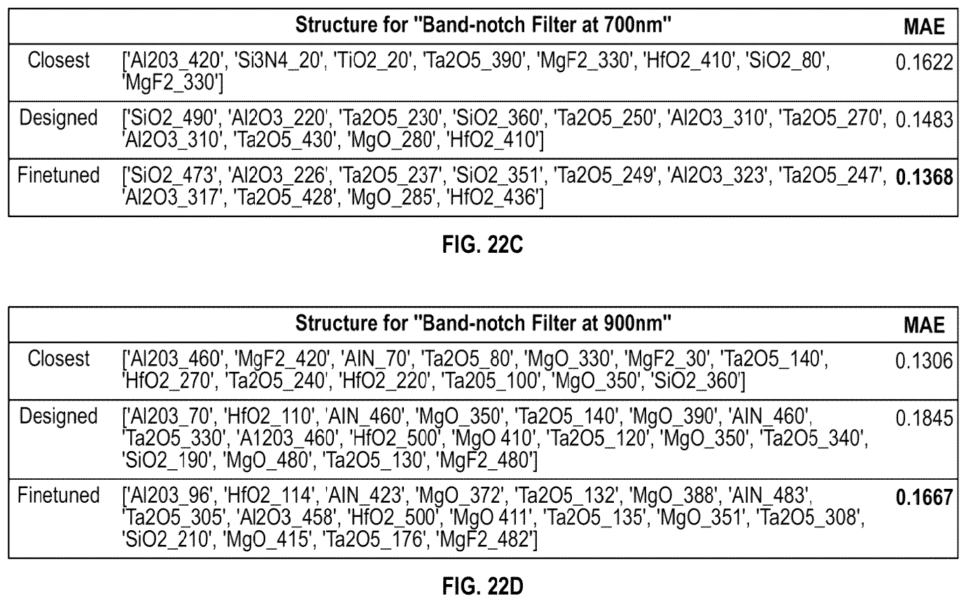

Referring now to FIGS. 22A-22D, more examples of inverse design band-notch filters at 700 nm (FIG. 22A) and 900 nm (at FIG. 22B) and corresponding structures are given in FIGS. 22C and 19D, respectively.

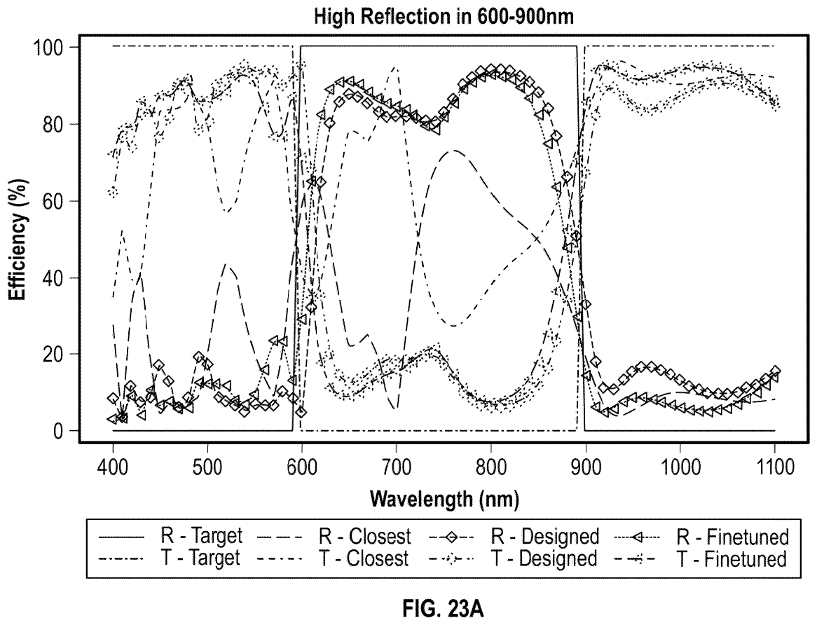

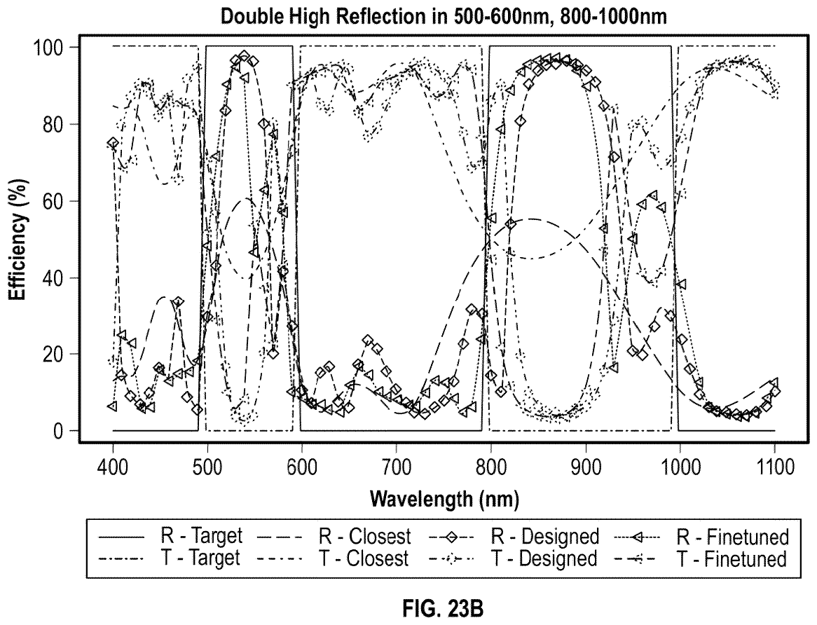

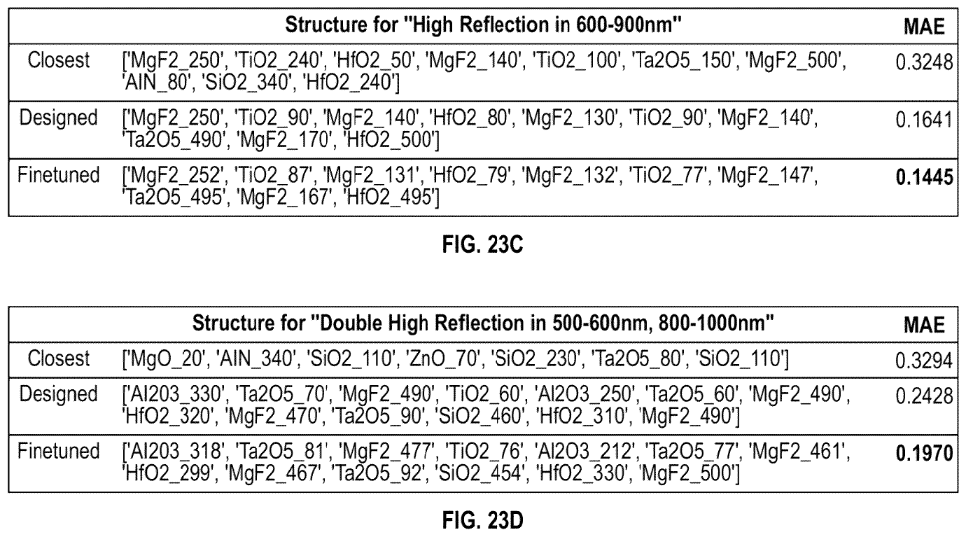

Referring now to FIGS. 23A-23D more details of inverse design DBR are illustrated. Three inverse design tasks for DBR are compared, but only one spectrum performance is illustrated. The details for the tasks “High Reflection in 600-900 nm” in FIG. 23A, “Double High Reflection in 500-600 nm, 800-1000 nm” in FIG. 23B are given here. The corresponding structures are given in FIGS. 23C and 23D, respectively.

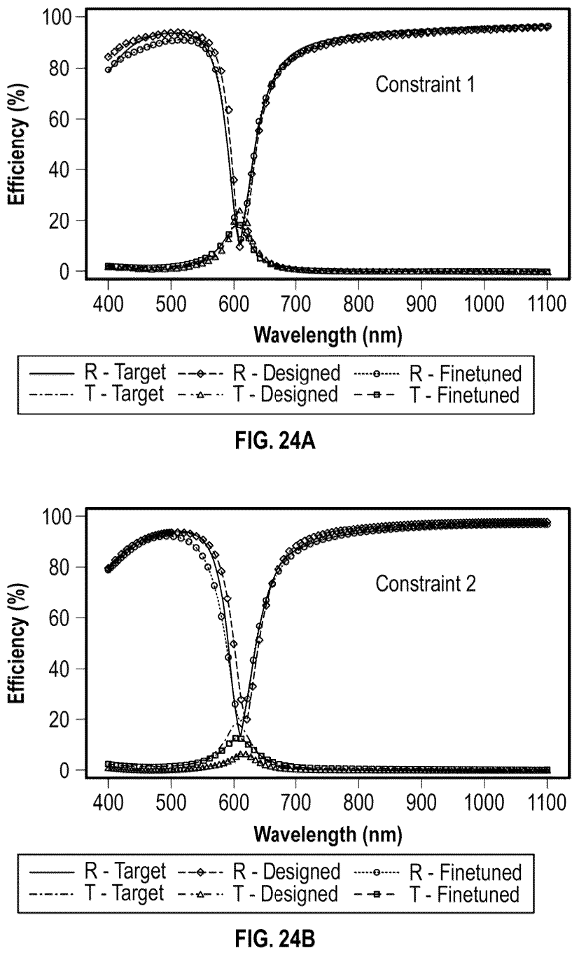

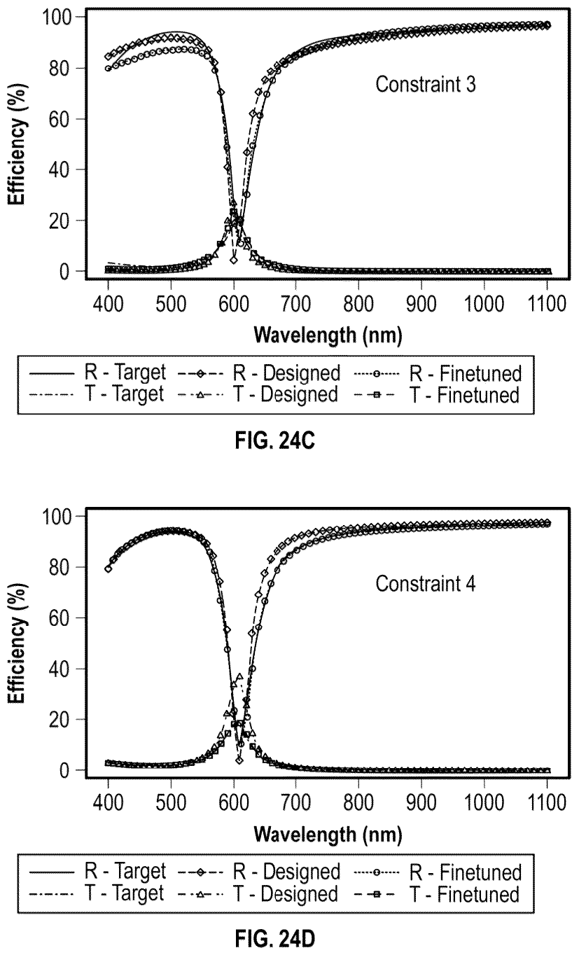

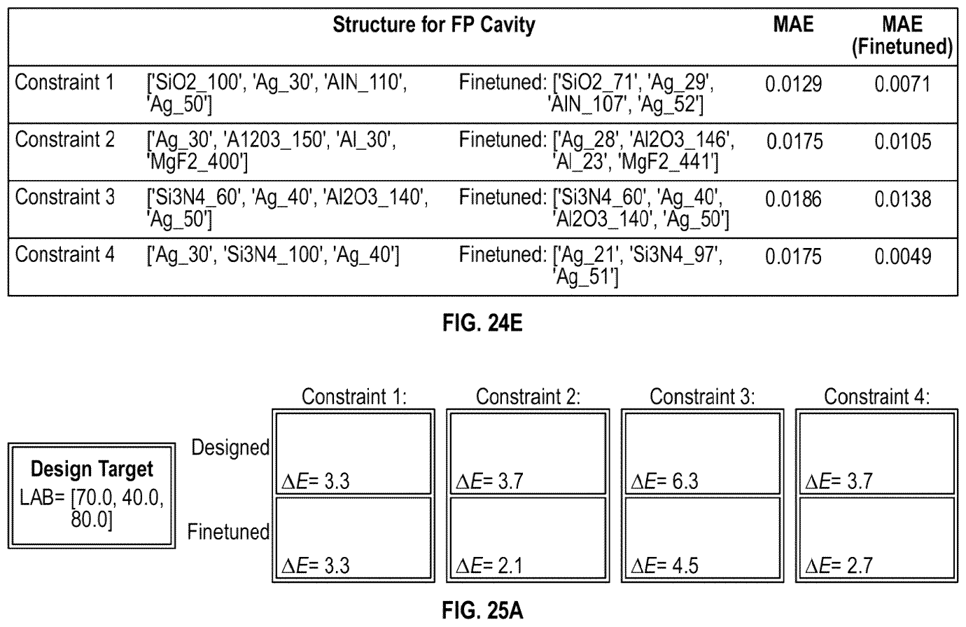

Referring now to FIGS. 24A-24D, detailed results of finetuning structures with the four constraints discussed above in FIG. 7A-E. Constraints 1-4 are “Fix the first layer to be 100 nm SiO₂”, “Remove Ag in the third layer”, “Limit the 427 thickness of the first layer inside [10, 150] nm and remove Ag/Al in the first layer”, and “Specify the material arrangement to be a three-layer Ag/Si₃N₄/Ag structure and design the thickness only.” Only the best structure (highlighted in FIG. 7B) is finetuned. FIGS. 24A-D show the spectrum of finetuned structures with constraints 1-4, respectively. FIG. 24E shows the detailed structures and spectrum performance.

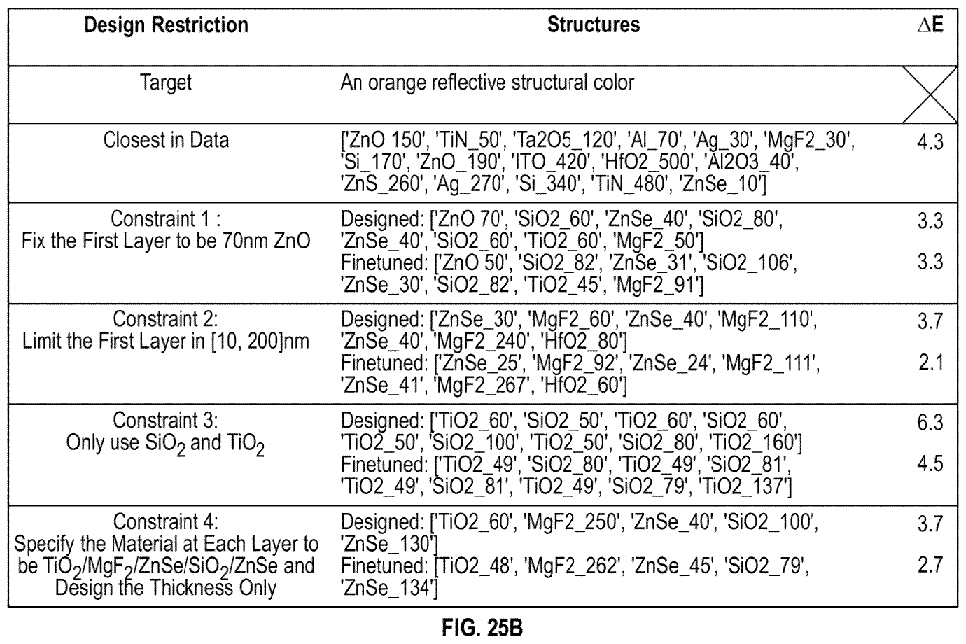

Referring now to FIGS. 25A-25B, another example of design flexibility for transmissive orange structural color LAB [70.0, 40.0, 80.0] is set forth. Here four different constraints were considered: “1: Fix the first layer to be 70 nm ZnO”, “2: Limit the first layer in [10, 200] nm”, “3: Only use SiO₂ and TiO₂”, “4: Specify the material at each layer to be TiO₂/MgF₂/ZnSe/SiO₂/ZnSe and design the thickness only”. The results of color impression ΔE are given in FIG. 25A. The designed structures are given in FIG. 25B.

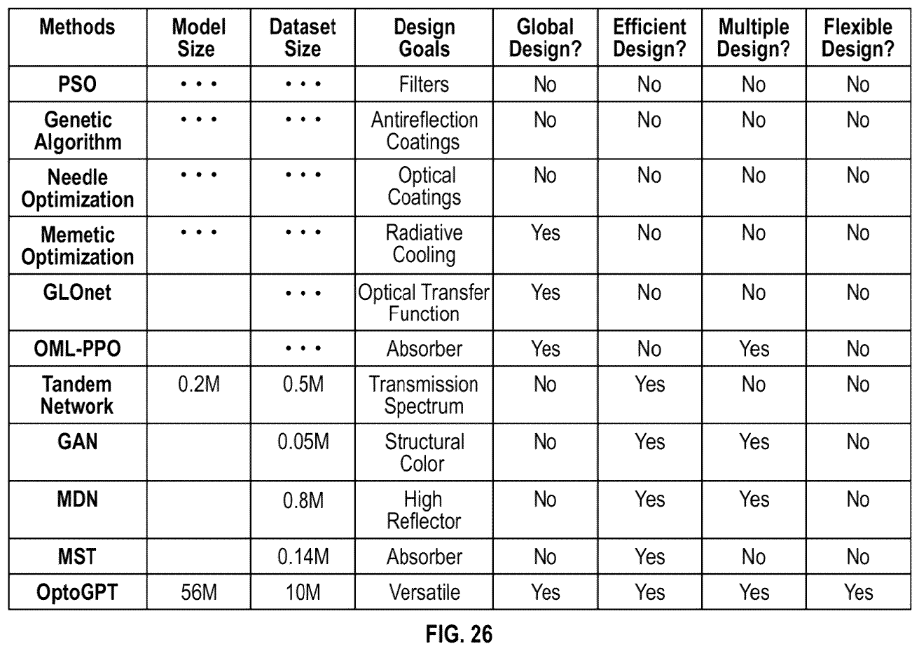

Referring now to FIG. 26, a table compares the model with existing methods from the following four aspects: (1) Global design: The method should be able to design for the total number of layers, material arrangements and thickness simultaneously. (2) Efficient design: The method should quickly adapt to different design targets without restarting the design process. (3) Multiple design: The method should output multiple designs. In principle, different designs may be obtained when the optimization process is restarted or retrained the model from different random points, so we do not consider this situation. (4) Flexible design: The method should be able to incorporate different design constraints without restarting the optimization process or retraining the model.

FIG. 26 illustrates that existing methods cannot resolve the conflict between global design and efficient design. The method of the present disclosure fills this gap and demonstrates promising performance outperforming existing methods.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements.

As used herein, the phrase at least one of A, B, and C should be construed to mean a logical (A OR B OR C), using a non-exclusive logical OR. For example, the phrase at least one of A, B, and C should be construed to include any one of: (i) A alone; (ii) B alone; (iii) C alone; (iv) A and B together; (v) A and C together; (vi) B and C together; (vii) A, B, and C together. The phrase at least one of A, B, and C should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information, but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A. The term subset does not necessarily require a proper subset. In other words, a first subset of a first set may be coextensive with (equal to) the first set.

The term “module” or the term “controller” may refer to, be part of, or include circuitry and/or processor hardware (shared, dedicated, or group) that executes code and memory hardware (shared, dedicated, or group) that stores code executed by the processor hardware.

The module or controller may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2016 (also known as the WIFI wireless networking standard) and IEEE Standard 802.3-2015 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module or controller may communicate with other modules or controllers using the interface circuit(s). Although the module or controller may be depicted in the present disclosure as logically communicating directly with other modules or controllers, in various implementations the module or controller may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module or controller may be distributed among multiple modules that are connected via the communications system. For example, multiple modules may implement the same functionality distributed by a load balancing system. In a further example, the functionality of the module or controller may be split between a server (also known as remote, or cloud) module and a client (or, user) module. For example, the client module may include a native or web application executing on a client device and in network communication with the server module.

The term code, as used above, may include software, firmware, and/or microcode, and may refer to programs, routines, functions, classes, data structures, and/or objects. Shared processor hardware encompasses a single microprocessor that executes some or all code from multiple modules or controllers. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of a non-transitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

The computer programs include processor-executable instructions that are stored on at least one non-transitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®, (vi) optical simulations such as TMM.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A method of performing inverse design of an optical multilayer thin film structure comprising:
receiving optical targets to a foundation model comprising a plurality of sequential decoders, the optical targets comprising a target spectrum;
receiving a hidden representation of the optical targets at the plurality of sequential decoders;
receiving physical embeddings and positional embeddings at a first decoder of the plurality of sequential decoders;
coupling an output of a previous decoder to a subsequent decoder of the plurality of sequential decoders; and
generating a sequence of tokens and probabilities representing a material and thickness for a plurality of layers of the optical multilayer thin film structure.

2. The method of claim 1, wherein receiving optical targets comprises receiving at least one of a structural color, an absorber, a filter, a distributed Bragg reflector and a Fabry-Pérot (FP) resonator.

3. The method of claim 1, wherein receiving optical targets comprises receiving reflection and transmission spectrum data.

4. The method of claim 1, wherein receiving optical targets comprises receiving polarization and direction of light output

5. The method of claim 1, wherein receiving the hidden representation comprises receiving the hidden representation to a multi-head cross attention layer of the first decoder.

6. The method of claim 5, wherein receiving the physical embeddings and the positional embeddings to the decoder comprises receiving the physical embeddings and the positional embeddings to a multi-head self-attention layer and providing an output of the multi-head self-attention layer to the multi-head cross attention layer.

7. The method of claim 1, wherein generating a sequence of tokens and probabilities comprises receiving constraints and generating the sequence and tokens with the constraints

8. The method of claim 1, wherein providing constraints comprises providing a single or multiple layer material limitation.

9. The method of claim 1, wherein providing constraints comprises providing a single or multiple layer thickness limitation.

10. The method of claim 1, further comprising outputting, with at least one processor, data representing a plurality of optical multilayer thin film structures.

11. The method of claim 10, further comprising determining Mean Absolute Errors (MAE) of data for each of the plurality of optical multilayer thin film structures and selecting one of the plurality of optical multilayer thin film structures with a lowest Mean Absolute Error.

12. The method of claim 11, further comprising selecting a combination of material and thickness based on the lowest Mean Absolute Error between a target spectrum.

13. The method of claim 1, wherein generating the sequence of tokens comprises generating a sequence of tokens by auto-regressively forming sequential layers.

14. A system of inverse designing an optical multilayer thin film structure comprising:
a computer-readable medium storing code for a foundation model having a transformer that includes neural network models and that utilizes structure serialization using tokens to represent materials and thicknesses of layers of optical multilayer thin film structures and that utilizes spectrum embedding to facilitate learning, by the model, of relationships between spectra and structure, the computer-readable medium also storing computer executable instructions that, when executed by a processor, configure the processor to:
receive optical target parameters as an input prompt;
generate data representing the optical multilayer thin film structure, based on the foundation model and the optical target parameters, the optical multilayer thin film structure having optical properties that satisfy the received optical target parameters; and
output the data representing the optical multilayer thin film structure.

15. The system of claim 14, wherein the data representing the optical multilayer thin film structure indicates a total number of layers of the optical multilayer thin film structure required to satisfy the optical target parameters and indicates a material and a thickness for each layer of the optical multilayer thin film structure.

16. The system of claim 14, wherein the optical target parameters comprise at least one of a structural color, an absorber, a filter, a distributed Bragg reflector and a Fabry-Pérot (FP) resonator.

17. The system of claim 14, wherein optical target parameters comprise reflection and transmission spectrum data.

18. A method for inverse design of an optical multilayer thin film structure comprising:
receiving, with at least one processor, optical target parameters based on an input prompt;
applying, with the at least one processor, the received optical target parameters to a foundation model having a transformer that includes neural network models and that utilizes structure serialization using tokens to represent materials and thicknesses of layers of optical multilayer thin film structures and that utilizes spectrum embedding to facilitate learning, by the model, of relationships between spectra and structure;
generating, with the at least one processor, data representing an optical multilayer thin film structure, based on an application of the foundation model to the optical target parameters, the optical multilayer thin film structure having optical properties that satisfy the received optical target parameters; and
outputting, with the at least one processor, the data representing the optical multilayer thin film structure.

19. The method of claim 18, wherein the data representing the optical multilayer thin film structure indicates a total number of layers of the optical multilayer thin film structure required to satisfy the optical target parameters and indicates a material and a thickness for each layer of the optical multilayer thin film structure.

20. The method of claim 18, wherein receiving optical target parameters comprises receiving at least one of a structural color, an absorber, a filter, a distributed Bragg reflector and a Fabry-Pérot (FP) resonator.

21. The method of claim 18 wherein receiving optical target parameters comprises receiving reflection and transmission spectrum data.
